(19) United States
(12) Patent Application Publication
(10) Pub. No.: US 2026/0213132 A1
(43) Pub. Date: Jul. 23, 2026

(54) Plasma Processing Device

(71) Applicant: Tokyo Electron Limited, Tokyo (JP)

(72) Inventors: Kazushi KANEKO, Yamanashi (JP); Satoru KAWAKAMI, Yamanashi (JP)

(21) Appl. No.: 19/568,882

(22) Filed: Mar. 17, 2026

Related U.S. Application Data
(63) Continuation of application No. PCT/JP2024/032803, filed on Sep. 13, 2024.

(30) Foreign Application Priority Data
Sep. 27, 2023 (JP) 2023-164674

(51) Int. Cl. H01J 37/32

(52) U.S. Cl. CPC H01J 37/32247; H01J 37/32201; H01J 37/32458; H01J 37/32715; H01J 2237/327

(57) ABSTRACT

A plasma processing apparatus includes a processing container, at least a portion of which is composed of a first dielectric, a substrate holding part configured to hold a plurality of substrates, an electromagnetic wave generator configured to generate electromagnetic waves for plasma excitation, an electromagnetic wave supply part configured to supply the electromagnetic waves into the processing container through the first dielectric, and a resonator array structure into which the electromagnetic waves are supplied through the first dielectric. The resonator array structure includes a plurality of resonators that are capable of resonating with a magnetic field component of the electromagnetic waves, that have sizes smaller than a wavelength of the electromagnetic waves, and that are disposed on the same plane. The electromagnetic wave supply part is configured to supply a magnetic field component perpendicular to the plane in which the plurality of resonators are arranged.

### CROSS-REFERENCE TO RELATED APPLICATIONS

This application is a bypass continuation application of International Application No. PCT/JP2024/032803 having an international filing date of Sep. 13, 2024 and designating the United States, the International Application being based upon and claiming the benefit of priority from Japanese Patent Application No. 2023-164674 filed on Sep. 27, 2023, the entire contents of which are incorporated herein by reference.

### TECHNICAL FIELD

The present disclosure relates to a plasma processing apparatus.

### BACKGROUND

Japanese Laid-open Patent Publication No. 2006-073913 discloses a plasma processing apparatus for performing a predetermined plasma process on an object to be processed, the apparatus comprising a processing container configured to allow vacuum suction, an object holding means for holding the object to be processed, a high-frequency power source for generating high-frequency voltage, a plasma gas supply means for supplying a gas to be plasmatized in the processing container, a pair of plasma electrodes connected to wiring and brought into an electrode excitation state together without being grounded to the output side of the high-frequency power source to generate plasma within the processing container, and a high-frequency matching means provided in the middle of the wiring.

### SUMMARY

The present disclosure provides a plasma processing apparatus capable of realizing high-densification of plasma.

A plasma processing apparatus in accordance with one embodiment of the present disclosure comprises a processing container, at least a portion of which is composed of a first dielectric, a substrate holding part configured to hold a plurality of substrates in the processing container, an electromagnetic wave generator configured to generate electromagnetic waves for plasma excitation that are supplied into the processing container, an electromagnetic wave supply part configured to supply the electromagnetic waves into the processing container through the first dielectric, and a resonator array structure disposed in a region of the processing container, into which the electromagnetic waves are supplied through the first dielectric, wherein the resonator array structure is configured to include a plurality of resonators that are capable of resonating with a magnetic field component of the electromagnetic waves, that have sizes smaller than a wavelength of the electromagnetic waves, and that are disposed on the same plane, and the electromagnetic wave supply part is configured to supply a magnetic field component perpendicular to the plane in which the plurality of resonators are arranged.

### BRIEF DESCRIPTION OF THE DRAWINGS

FIG. 1 is a schematic vertical cross-sectional view illustrating an exemplary configuration of a plasma processing apparatus according to a first embodiment of the present disclosure.

FIG. 2 is a schematic horizontal cross-sectional view illustrating an exemplary configuration of a plasma processing apparatus according to the first embodiment.

FIG. 3 shows an exemplary configuration of a resonator array structure according to the first embodiment.

FIG. 4 is a cross-sectional view illustrating an example of an IV-IV cross-section of FIG. 3.

FIG. 5 illustrates an example of a plane and a V-V cross-section of a single resonator body according to the first embodiment.

FIG. 6 is a cross-sectional view illustrating an example of a VI-VI cross-section of FIG. 5.

FIG. 7 is a cross-sectional view illustrating an example of a VII-VII cross-section of FIG. 5.

FIG. 8 illustrates an example of calculation of a resonance frequency of the resonator according to the first embodiment.

FIG. 9 is a schematic horizontal cross-sectional view illustrating an exemplary configuration of a plasma processing apparatus according to Modification 1.

FIG. 10 is a schematic vertical cross-sectional view illustrating an exemplary configuration of a plasma processing apparatus according to Modification 2.

FIG. 11 is a schematic horizontal cross-sectional view illustrating an exemplary configuration of a plasma processing apparatus according to the Modification 2.

FIG. 12 is a schematic horizontal cross-sectional view illustrating an exemplary configuration of a plasma processing apparatus according to Modification 3.

FIG. 13 is a schematic horizontal cross-sectional view illustrating an exemplary configuration of a plasma processing apparatus according to Modification 4.

FIG. 14 is a schematic vertical cross-sectional view illustrating an exemplary configuration of a plasma processing apparatus according to Modification 5.

FIG. 15 illustrates an exemplary configuration of a resonator array structure according to Modification 6.

FIG. 16 illustrates an exemplary configuration of a resonator array structure according to Modification 7.

FIG. 17 illustrates an exemplary configuration of a resonator array structure according to Modification 8.

FIG. 18 is a schematic horizontal cross-sectional view illustrating an exemplary configuration of a plasma processing apparatus according to a second embodiment.

FIG. 19 illustrates an exemplary configuration of a resonator array structure according to the second embodiment.

FIG. 20 illustrates an exemplary configuration of a resonator according to the second embodiment.

FIG. 21 illustrates an exemplary configuration of a resonator according to the second embodiment.

FIG. 22 illustrates another exemplary configuration of a resonator according to the second embodiment.

FIG. 23 shows an example of a cross-section of a resonator according to the second embodiment.

FIG. 24 is a schematic horizontal cross-sectional view illustrating an exemplary configuration of a plasma processing apparatus according to Modification 9.

FIG. 25 is a schematic horizontal cross-sectional view illustrating an exemplary configuration of a plasma processing apparatus according to Modification 10.

FIG. 26 is a schematic horizontal cross-sectional view illustrating an exemplary configuration of a plasma processing apparatus according to Modification 11.

FIG. 27 is a schematic horizontal cross-sectional view illustrating an exemplary configuration of a plasma processing apparatus according to Modification 12.

FIG. 28 is a schematic horizontal cross-sectional view illustrating an exemplary configuration of a plasma processing apparatus according to Modification 13.

FIG. 29 is a schematic horizontal cross-sectional view illustrating an exemplary configuration of a plasma processing apparatus according to Modification 14.

FIG. 30 is a schematic vertical cross-sectional view illustrating an exemplary configuration of a plasma processing apparatus according to Modification 15.

FIG. 31 is a schematic vertical cross-sectional view illustrating an exemplary configuration of a plasma processing apparatus according to Modification 16.

FIG. 32 illustrates an exemplary configuration of a resonator array structure according to Modification 17.

FIG. 33 illustrates an exemplary configuration of a resonator array structure according to Modification 18.

FIG. 34 illustrates an exemplary configuration of a resonator array structure according to Modification 19.

FIG. 35 illustrates an exemplary configuration of a resonator array structure according to Modification 20.

FIG. 36 illustrates an exemplary configuration of an RF power feeding system according to the first and second embodiments.

FIG. 37 illustrates exemplary settings for a resonance frequency of a resonator and an output of an RF power source according to the first and second embodiments.

FIG. 38 illustrates an exemplary configuration of an RF power feeding system according to the first and second embodiments.

FIG. 39 illustrates exemplary settings for a resonance frequency of a resonator and an output of an RF power source according to the first and second embodiments.

FIG. 40 illustrates exemplary settings for a resonance frequency of a resonator and an output of an RF power source according to the first and second embodiments.

FIG. 41 illustrates exemplary configuration of an RF power feeding system according to Modifications 5, 16 and 16.

FIG. 42 is a schematic vertical cross-sectional view illustrating an exemplary configuration of a plasma processing apparatus according to the third embodiment.

FIG. 43 is a schematic horizontal cross-sectional view illustrating an exemplary configuration of a plasma processing apparatus according to the third embodiment.

FIG. 44 is a side view illustrating an exemplary configuration of a resonator array structure according to the third embodiment.

FIG. 45 is a plan view illustrating an exemplary configuration of the resonator array structure seen along the XLV-XLV cross-section of FIG. 44.

FIG. 46 is a schematic horizontal cross-sectional view illustrating an exemplary configuration of a plasma processing apparatus according to Modification 21.

FIG. 47 is a schematic vertical cross-sectional view illustrating an exemplary configuration of a plasma processing apparatus according to Modification 22.

FIG. 48 is a schematic vertical cross-sectional view illustrating an exemplary configuration of a plasma processing apparatus according to Modification 23.

FIG. 49 is a plan view illustrating an exemplary configuration of a resonator array structure according to Modification 24.

FIG. 50 is a plan view illustrating an exemplary configuration of a resonator array structure according to Modification 25.

FIG. 51 illustrates a relationship between a resonator array structure and a substrate according to the Modification 25.

FIG. 52 is a plan view illustrating an exemplary configuration of a resonator array structure according to Modification 26.

FIG. 53 is a view illustrating an exemplary configuration of a resonator according to Modification 27.

FIG. 54 is a schematic vertical cross-sectional view illustrating an exemplary configuration of a plasma processing apparatus according to a fourth embodiment.

FIG. 55 is a schematic vertical cross-sectional view illustrating an exemplary configuration of a plasma processing apparatus according to Modification 28.

FIG. 56 is a side view illustrating an exemplary configuration of a resonator array structure according to the fourth embodiment and the Modification 28.

FIG. 57 is a plan view illustrating an exemplary configuration of the resonator array structure seen along the LVII-LVII cross-section of FIG. 56.

FIG. 58 is a plan view illustrating an exemplary configuration of a resonator array structure according to Modification 29.

FIG. 59 is a plan view illustrating an exemplary configuration of a resonator array structure according to Modification 30.

FIG. 60 illustrates a relationship between a resonator array structure and a substrate according to the Modification 30.

FIG. 61 illustrates an exemplary configuration of an RF power feeding system according to the fourth embodiment.

### DETAILED DESCRIPTION

Hereinafter, exemplary embodiments of a plasma processing apparatus according to the present disclosure will be described with reference to the accompanying drawings. Further, it should be understood that the present disclosure is not limited to the exemplary embodiments described below.

However, a plasma processing apparatus using microwaves for plasma excitation occasionally increases the power of microwaves supplied into a processing container to raise electron density of plasma. The electron density of the plasma may be increased proportionally as the power of the microwaves supplied into the processing container is increased.

Here, it is known that if the electron density of the plasma reaches a specific upper limit due to an increase of the power of the microwaves supplied into the processing container, the permittivity of the space within the processing container becomes a negative value. The upper limit of electron density is appropriately referred to as “cutoff density.” Also, a refractive index is known as an index indicating whether microwaves propagate through a space. The refractive index N is expressed by Eq. (1) below.

$$N = \sqrt{ε} \sqrt{μ} \qquad ( 1 )$$

In Eq. (1), ε represents permittivity, and μ represents permeability.

Since permeability is generally a positive value, if the permittivity of a space within the processing container becomes a negative value, the refractive index of the space within the processing container becomes a pure imaginary number according to Eq. (1) above. Consequently, microwaves are attenuated and may not propagate through the space within the processing container. In this manner, when the electron density of the plasma reaches a cutoff density, the microwave power is not sufficiently absorbed into the plasma because the microwaves may not propagate in the space within the processing container. As a result, a problem arises in that the extensive high-densification of plasma generated within the processing container is inhibited. Furthermore, although microwaves have been described as an example above, the same problem exists in plasma processing apparatuses using electromagnetic waves in the very high frequency (VHF) to ultra-high frequency (UHF) bands.

Also, in a so-called batch-type plasma processing apparatus, it may be difficult to improve plasma density because the distance between a remote plasma source and a substrate, which is an object to be processed, is long. Furthermore, in a batch-type plasma processing apparatus, when strip-shaped flat plate electrodes are used in the longitudinal direction of a processing container for plasma generation, variations may occur in the progress of plasma processing among a plurality of substrates due to the distribution of voltage standing waves. Moreover, in a batch-type plasma processing apparatus in which multi-stage electrodes connected to a high-frequency power source are provided between a plurality of substrates, provision of wiring within the processing container leads to problems such as discharge from the wiring or short circuits between wires due to a breakdown voltage of a standing wave. Additionally, when high-frequency power is individually fed to the multi-stage electrodes, phase control or isolation is required so that the standing waves of the respective electrodes do not interfere with each other. Therefore, it is expected to realize high-densification of plasma by performing non-contact power feeding within the processing container.

### First Embodiment

### [Configuration of Plasma Processing Apparatus]

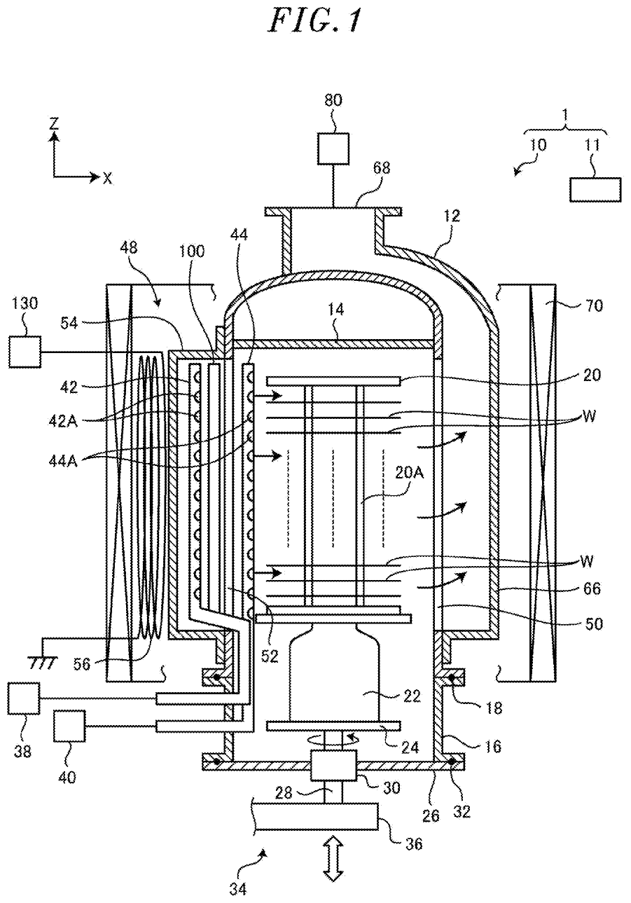

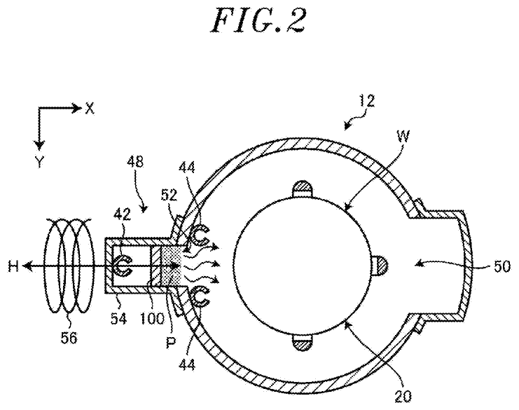

FIG. 1 is a schematic vertical cross-sectional view illustrating an exemplary configuration of a plasma processing apparatus according to a first embodiment of the present disclosure. FIG. 2 is a schematic horizontal cross-sectional view illustrating an exemplary configuration of a plasma processing apparatus according to the first embodiment. A plasma processing apparatus 1 comprises an apparatus main body 10 and a control device (an example of a controller) 11. The plasma processing apparatus 1 shown in FIGS. 1 and 2 is configured, for example, as an inductively coupled plasma processing apparatus. The apparatus main body 10 includes a processing container 12, a wafer boat 20, gas suppliers 38 and 40, an antenna 56, a resonator array structure 100, and a Radio Frequency (RF) power source (an example of an electromagnetic wave generator) 130.

The processing container 12 is formed in a cylindrical shape having an open lower end and a ceiling. The entirety of the processing container 12 is formed of, for example, quartz, and a ceiling plate 14 made of quartz is provided on the ceiling within the processing container 12 and is sealed. The quartz forming the processing container 12 is an example of a first dielectric. Also, a manifold 16 molded into a cylindrical shape by, for example, stainless steel is connected to the lower end opening of the processing container 12 with a sealing member 18 such as an O-ring interposed therebetween.

The lower end of the processing container 12 is supported by the manifold 16. At the lower end of the processing container 12, a wafer boat 20 made of quartz, on which a plurality of substrates W as objects to be processed are mounted in multiple stages, is installed in a way to be raised and lowered from the lower part of the manifold 16, and the wafer boat 20 may be loaded and unloaded to and from the lower end of the processing container 12. The wafer boat 20 is an example of a substrate holding part. On pillars 20A of the wafer boat 20, for example, about 30 substrates W having a diameter of 300 mm may be supported in multiple stages at a substantially constant pitch. The wafer boat 20 is mounted on a table 24 with a heat-insulating cylinder 22 made of quartz interposed therebetween. The table 24 is supported on a rotating shaft 28 passing through a cover 26 made of, for example, stainless steel, which opens and closes the lower end opening of the manifold 16. A magnetic fluid seal 30, for example, is provided at a penetrating portion of the rotating shaft 28 to rotatably support the rotating shaft 28 while hermetically sealing it. Also, a sealing member 32 such as an O-ring is provided in the peripheral portion of the cover 26 and the lower end of the manifold 16, thereby maintaining sealability within the processing container 12.

The rotating shaft 28 is installed at the tip of an arm 36 supported by a lifting mechanism 34, such as a boat elevator, and is capable of being loaded and unloaded to and from the processing container 12 by integrally raising and lowering the wafer boat 20 and the cover 26. Alternatively, a table 24 may be fixedly provided on the side of the cover 26, and processing of the substrate W may be performed without rotating the wafer boat 20. The manifold 16 is provided with a gas supplier 38 that supplies a gas to be plasmatized, for example, ammonia gas NH₃, into the processing container 12, and a gas supplier 40 that supplies a film-forming gas, for example, hexachlorodisilane gas HCD as a silane-based gas.

A plasma gas distribution nozzle 42, which is made of a quartz tube that penetrates a sidewall of the manifold 16 toward the inside thereof and then bends and extends in an upward direction, is connected to the gas supplier 38. A plurality of gas injection holes 42A are formed at predetermined intervals along the longitudinal direction of the plasma gas distribution nozzle 42, thereby allowing plasma gas to be injected substantially uniformly through each gas injection hole 42A in a horizontal direction. The gas supplier 38 may be configured to supply, for example, hydrogen gas H₂ or an inert gas in addition to ammonia gas NH₃ as the gas to be plasmatized. The inert gas is, for example, argon gas Ar or nitrogen gas N₂.

A film-forming gas distribution nozzle 44, which is made of a quartz tube that penetrates a sidewall of the manifold 16 toward the inside thereof and then bends and extends in an upward direction, is connected to the gas supplier 40. Here, two film-forming gas distribution nozzles 44 are provided (refer to FIG. 2). A plurality of gas injection holes 44A are formed at predetermined intervals along the longitudinal direction of each film-forming gas distribution nozzle 44, thereby allowing the film-forming gas to be injected substantially uniformly through each gas injection hole 44A in a horizontal direction. The gas supplier 40 may be configured to supply, as the film-forming gas, a silane-based gas such as dichlorosilane SiH₂Cl₂, monosilane SiH₄, disilane Si₂H₆, hexamethyldisilazane HMDS, monochlorosilane SiH₃ Cl trichlorosilane SiHCl₃, tetrachlorosilane SiCl₄, or disilylamine DSA gas. In addition, the gas supplier 40 may be configured to supply trisilylamine TSA or bis(tertiary-butylamino) silane BTBAS gas as the film-forming gas.

A plasma generator 48 is formed along the height direction in a portion of the sidewall of the processing container 12. Also, a thin and elongated exhaust port 50, which is formed by cutting the sidewall of the processing container 12, for example, in the vertical direction, is provided on the opposite side of the processing container 12 facing the plasma generator 48. The exhaust port 50 is configured to vacuum-exhaust the interior of the processing container 12. In the plasma generator 48, a thin and elongated opening 52 is formed in the vertical direction by cutting the sidewall of the processing container 12 with a predetermined width along the vertical direction. In the plasma generator 48, a vertically elongated plasma partition wall 54 made of, for example, quartz and having a concave cross-sectional shape is formed to be integrated with the inside of the container by being hermetically weld-bonded to the outer wall of the container, so as to cover the opening 52 from the outside. Accordingly, by causing a portion of the sidewall of the processing container 12 to protrude outward in a concave manner, the plasma generator 48 is formed, one side of which is opened to and connected with the inside of the processing container 12. In other words, the internal space of the plasma generator 48 is in a state of being integrally connected with the interior of the processing container 12. The opening 52 is formed sufficiently long in the vertical direction to cover all the substrates W held by the wafer boat 20 in the height direction. Also, a resonator array structure 100 is provided in the internal space of the plasma generator 48, i.e., between the sidewalls of the plasma partition wall 54. It should be noted that the plasma generator 48 is an example of a plasma generation chamber partitioned and formed by the plasma partition wall 54. Therefore, the resonator array structure 100 is provided in the plasma generation chamber partitioned and formed by the plasma partition wall 54 provided along the longitudinal direction of the processing container 12.

An antenna 56 is provided along the longitudinal direction (vertical direction) on the outer surface of the wall at the end side of the plasma partition wall 54. The antenna 56 includes, for example, a solenoid-shaped coil. In other words, the antenna 56 is wound in a loop shape. It should be noted that the opening of the antenna 56 may have any shape such as a circle, an ellipse, or a polygon (e.g., a quadrilateral or a triangle). An RF power source 130 is connected to the antenna 56, and a source RF signal is supplied thereto. The magnetic field H generated by the antenna 56 is in the direction of the X-axis shown in FIGS. 1 and 2.

The RF power source 130 is coupled to the antenna 56 and is configured to generate a source RF signal (source RF power) for plasma generation through at least one impedance matching circuit. In one embodiment, the source RF signal has a frequency within a range of 10 MHz to 3000 MHz. In one embodiment, the RF power source 130 may be configured to generate a plurality of source RF signals having different frequencies. The generated one or more source RF signals are supplied to the antenna 56. As described above, the RF power source 130 is an example of an electromagnetic wave generator and an example of a high-frequency power source. Also, the antenna 56 is an example of an electromagnetic wave supply part.

In the plasma generator 48, the plasma gas distribution nozzle 42 extends upward within the processing container 12 and is then bent radially outward from the processing container 12, thereby being located on the outer side of the resonator array structure 100 within the plasma generator 48 (opposite to the center side of the processing container 12). The plasma gas distribution nozzle 42 is provided upright in the plasma generator 48 toward the upper side. Therefore, the gas to be plasmatized injected from the gas injection holes 42A of the plasma gas distribution nozzle 42 is configured to flow toward the center of the processing container 12 while diffusing through the resonator array structure 100. The gas to be plasmatized is excited by electromagnetic waves supplied to the internal space of the plasma generator 48 from the antenna 56 through the plasma partition wall 54 and the resonator array structure 100. Accordingly, the gas to be plasmatized is converted into plasma in the internal space of the plasma generator 48. Also, the gas to be plasmatized may flow toward the center of the processing container 12 through gaps near the resonator array structure 100. Ions, radicals, and the like included in the plasma are directed toward the center of the processing container 12.

Two film-forming gas distribution nozzles 44 are provided upright near the outer side of the opening 52 of the plasma generator 48, that is, on both sides of the outer side of the opening 52 (inside the processing container 12). Near the opening 52, the film-forming gas is injected toward the center of the processing container 12 from each gas injection hole 44A provided in each film-forming gas distribution nozzle 44. The ions, radicals, and the like included in the plasma and the film-forming gas flow in a laminar flow state between the substrates W to process the substrates W. For example, a silicon nitride film is formed on the substrate W.

An exhaust port cover member 66 is attached by welding to the exhaust port 50 provided to face the plasma generator 48, wherein the exhaust port cover member 66 is made of quartz and formed with one side open so as to cover the exhaust port 50. The exhaust port cover member 66 extends upward along the sidewall of the processing container 12 and is vacuum-exhausted from a gas outlet 68 at the upper part of the processing container 12 by a vacuum exhaust system in which a vacuum pump (not shown) is interposed. Also, a cylindrical heater 70 for heating the processing container 12 and the substrates W therein is provided outside the processing container 12 so as to surround the outer periphery of the processing container 12.

The resonator array structure 100 is formed by arranging a plurality of resonators capable of resonating with a magnetic field component of electromagnetic waves and having a size smaller than the wavelength of the electromagnetic waves, and is located in a region within the processing container 12 where the electromagnetic waves may be supplied through the plasma partition wall 54. The corresponding region is, for example, the internal space of the plasma generator 48. The resonator array structure is also called a metamaterial, and the resonator is also called a meta-atom.

By the resonator array structure 100 being located in the corresponding region within the processing container 12, the electromagnetic waves supplied by the antenna 56 to the processing space, which is the internal space of the processing container 12, may resonate with the plurality of resonators of the resonator array structure 100. Here, the internal space of the processing container 12 also includes the internal space of the plasma generator 48. Due to the resonance between the electromagnetic waves and the plurality of resonators, the electromagnetic waves may be efficiently supplied to the processing space of the processing container 12, and the permeability of the processing space may be made to have a negative value. When the permeability of the processing space is a negative value, even if the electron density of the plasma generated in the processing space reaches the cutoff density and the permittivity of the processing space becomes a negative value, the electromagnetic waves may propagate in the processing space because the refractive index becomes a real number according to Eq. (1) above. Accordingly, even when the electron density of the plasma generated in the processing space reaches the cutoff density, the electromagnetic waves may propagate beyond the skin depth of the plasma, thereby allowing the power of the electromagnetic waves to be efficiently absorbed into the plasma. As a result, high-density plasma may be generated in a wide range beyond the skin depth of the plasma. In other words, according to the plasma processing apparatus 1 of the present embodiment, the plasma may be highly densified in a wide range by the resonator array structure 100 being located in the region within the processing container 12 where the electromagnetic waves may be supplied through the plasma partition wall 54.

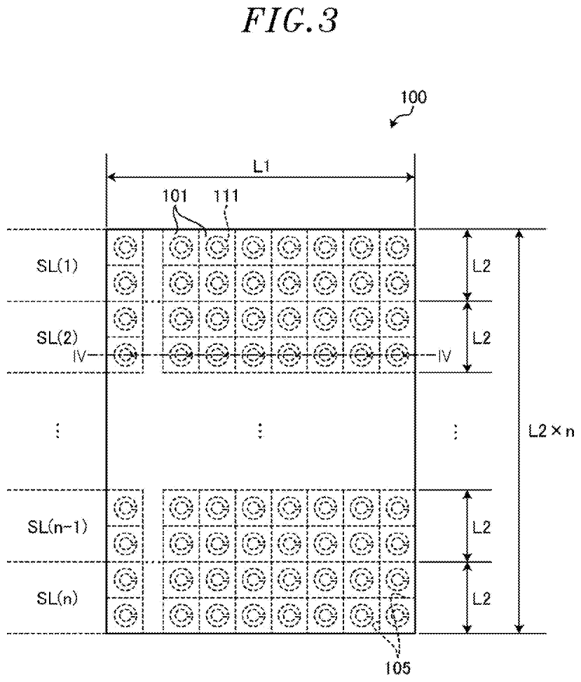

Here, a detailed configuration of the resonator array structure 100 will be described with reference to FIGS. 1 to 3. FIG. 3 shows an exemplary configuration of a resonator array structure according to the first embodiment. FIG. 3 shows the resonator array structure 100 as viewed from the wafer boat 20 side in the X-axis direction of FIG. 1. The resonator array structure 100 is formed sufficiently long in the vertical direction to cover all the substrates W held in the wafer boat 20 along the height direction.

As shown in FIGS. 1 and 2, the resonator array structure 100 is disposed in the internal space of the plasma generator 48. In the present embodiment, plasma P is generated on the wafer boat 20 side of the resonator array structure 100 in the internal space of the plasma generator 48.

The resonator array structure 100 is formed by arranging a plurality of resonators 101 in a lattice shape, the plurality of resonators being capable of resonating with the magnetic field component of the electromagnetic waves and having a size smaller than the wavelength of the electromagnetic waves. Specifically, as shown in FIG. 3, the plurality of resonators 101 are disposed on the same plane in the flat-plate-shaped resonator array structure 100. In other words, the plurality of resonators 101 are disposed on a plane parallel to the longitudinal surface of the resonator array structure 100. In other words, when viewed from the wafer boat 20 side, C-shaped ring members 111 shown transparently are arranged in a lattice shape so that the C-shape is visible. In the resonator array structure 100, for example, a plurality of columns of resonators 101 are arranged in a column direction (horizontal direction) according to the width of the internal space of the plasma generator 48, and two rows of resonators 101 are arranged per one slot SL for accommodating the substrate W in the wafer boat 20 in a row direction (vertical direction). In the example of FIG. 3, when n substrates W are accommodated in the wafer boat 20, slots SL(1) to SL(n) are formed, and 2n rows of resonators 101 are arranged in the row direction. In other words, the size of the resonator array structure 100 may be expressed using L1 in the column direction and L2×n in the row direction, where L1 is the width of the resonator array structure 100 in the column direction and L2 is the length of one slot SL in the row direction.

At this time, although the boundary of each of the plurality of resonators 101 is indicated by a boundary 105, the plurality of resonators 101 are actually integrally formed as the resonator array structure 100. It should be noted that the resonator array structure 100 may also be configured by forming the plurality of resonators 101 separately and inserting them into a lattice-shaped frame or bonding them to each other. Each of the plurality of resonators 101 constitutes a series resonance circuit composed of a capacitor equivalent element and a coil equivalent element. The series resonance circuit is realized by patterning a conductor on a plane. Also, the resonator array structure 100 may have through-holes through which gas to be plasmatized can pass. Furthermore, the magnetic field H generated by the antenna 56 is in a direction passing through the C-shaped ring member 111.

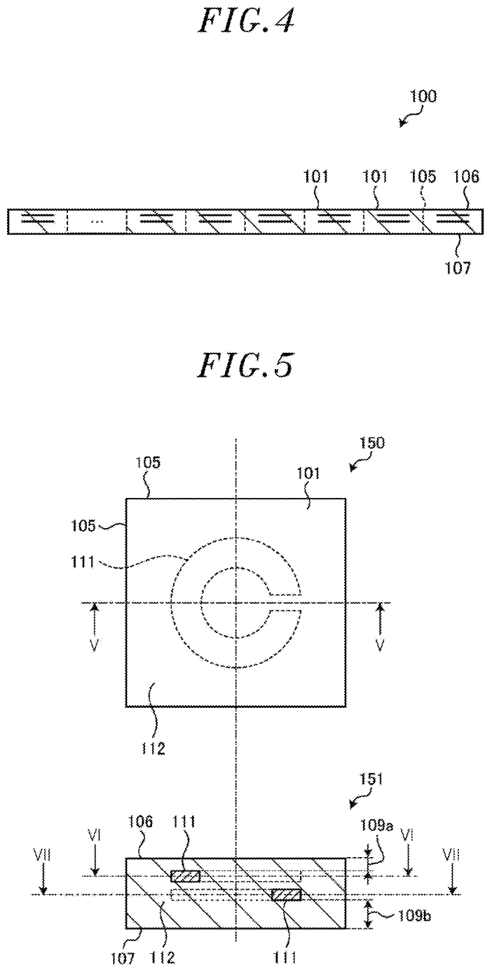

FIG. 4 is a cross-sectional view illustrating an example of an IV-IV cross-section of FIG. 3. As shown in FIG. 4, in the IV-IV cross-section of the resonator array structure 100, cross-sections of a plurality of resonators 101 are arranged side by side. Also, similarly to FIG. 3, the boundary of each of the plurality of resonators 101 is indicated as boundary 105. Here, a first surface 106 of the resonator array structure 100 is a surface facing toward the center side of the processing container 12 (the wafer boat 20 side), and a second surface 107 is a surface facing toward the antenna 56 side.

FIG. 5 illustrates an example of a plane and a V-V cross-section of a single resonator body according to the first embodiment. In FIG. 5, taking one of the plurality of integrally formed resonators 101 as an example, a plan view 150 of the single resonator 101 and a cross-sectional view 151 of the V-V cross-section of the plan view 150 are shown. As shown in the plan view 150 and the cross-sectional view 151, the single resonator 101 is within a region surrounded by the boundary 105. In other words, in the present embodiment, the resonator 101 is in a state in which two C-shaped ring members 111 are each surrounded by a dielectric 112. The dielectric 112 is an example of a second dielectric. The dielectric 112 is formed such that thickness 109a from the first C-shaped ring member 111 to the first surface 106 is thinner than thickness 109b from the second C-shaped ring member 111 to the second surface 107. Accordingly, in the resonator array structure 100, plasma may be selectively generated on the first surface 106 side, which is the wafer boat 20 side. In other words, the resonator array structure 100 may control the plasma generation surface based on the thickness of the dielectric 112 from each ring member 111 of the resonator 101 to the surface.

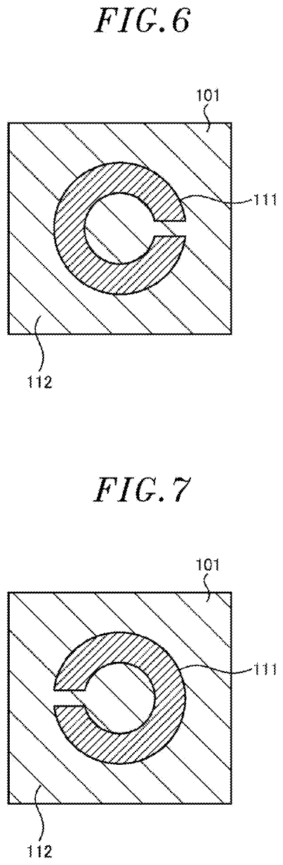

FIG. 6 is a cross-sectional view illustrating an example of a VI-VI cross-section of FIG. 5. FIG. 7 is a cross-sectional view illustrating an example of a VII-VII cross-section of FIG. 5. As shown in the cross-sectional view 151 of FIG. 5 and in FIGS. 6 and 7, the single resonator 101 has a structure in which the dielectric 112 is disposed between two C-shaped ring members 111 are made of a conductor, the two C-shaped ring members 111 being disposed adjacent to each other in opposite directions. In other words, in the resonator 101, the dielectric 112 is sandwiched between the two C-shaped ring members 111 facing opposite directions. Capacitor equivalent elements are formed at facing surfaces of the two C-shaped ring members 111 or at both ends of each ring member 111, and a coil equivalent element is formed along each ring member 111. Accordingly, the resonator 101 may constitute a series resonance circuit. Also, in the resonator 101 shown in FIGS. 5 to 7, the number of disposed C-shaped ring members 111 (hereinafter, appropriately referred to as “the number of layers”) is two, but the number of layers of the C-shaped ring members 111 may be greater than two. In this case, the resonator 101 has a structure in which C-shaped ring members 111 are disposed adjacent to each other in opposite directions and the dielectric 112 is disposed between the C-shaped ring members 111.

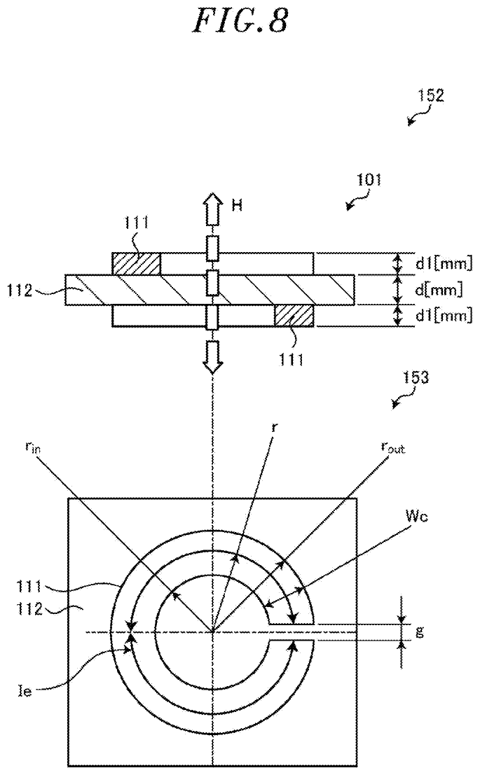

Here, the resonance frequency of the resonator 101 will be described with reference to FIG. 8. FIG. 8 illustrates an example of calculating of a resonance frequency of the resonator according to the first embodiment. As shown in the cross-sectional view 152 of FIG. 8, the resonator 101 may be recognized as having a structure in which the dielectric 112 is sandwiched between two C-shaped ring members 111. At this time, when a magnetic field H passing through the C-shaped ring member 111 of the resonator 101 is generated, an induced current le is generated in the C-shaped ring member 111. In FIG. 8, the dielectric 112 surrounding the outside of the C-shaped ring member 111 is omitted.

Meanwhile, the resonance frequency of the resonator 101 may be obtained from each dimension in the cross-sectional view 152 and the plan view 153 of FIG. 8. In other words, the resonance frequency of the resonator 101 may be obtained as shown in Eqs. (2) to (5) from the dimensions of the C-shaped ring member 111 and the thickness of the dielectric 112 sandwiched between the two C-shaped ring members 111. Equation (2) is used for obtaining inductance L_{MA} of the resonator 101. Equation (3) is used for obtaining capacitance C_{half} corresponding to an upper half or a lower half of the plan view 153 among the capacitance C_{MA} of the resonator 101. Equation (4) is used for obtaining the capacitance C_{MA} as the resonator 101. Equation (5) is used for obtaining resonance frequency Fᵣ of the resonator 101.

$$[ Eq . 1 ]$$

$${L}_{MA} = {μ}_{0} r ( log ( 4 π ) - 1 ) \qquad ( 1 )$$

$$[ Eq . 2 ]$$

$${C}_{half} = ε {ε}_{0} \frac{S}{d} = ε {ε}_{0} \frac{( π ( {r}_{out}^{2} - {r}_{in}^{2} ) - {S}_{split} ) / 2}{{d}_{PTFE}} \qquad ( 2 )$$

$$[ Eq . 3 ]$$

$${C}_{MA} = \frac{1}{\frac{1}{{C}_{half}} + \frac{1}{{C}_{half}}} \qquad ( 3 )$$

$$[ Eq . 4 ]$$

$$Fr = \frac{1}{2 π \sqrt{{L}_{MA} {C}_{MA}}} \qquad ( 4 )$$

In Eq. (2), r represents the radius from the center of the C-shaped ring member 111 to the center of the width of the C-shape, and μ₀ represents the permeability of vacuum. In Eq. (3), C_{half} represents the capacitance corresponding to the upper half or the lower half of the plan view 153 among the capacitances of the resonator 101. Also, in Eq. (3), ε is the permittivity, ε₀ is the permittivity of vacuum (electric constant), S is the region of the upper half or the lower half of the C-shaped ring member 111, and d represents the spacing between the two C-shaped ring members 111. Furthermore, in Eq. (3), rₒᵤₜ represents the outer radius of the C-shaped ring member 111, rᵢₙ represents the inner radius of the C-shaped ring member 111, and Sₛₚₗᵢₜ represents the region of the gap of the C-shape of the C-shaped ring member 111. Also, Sₛₚₗᵢₜ may be approximately obtained as a rectangular region from the width W_{c} of the C-shaped ring member 111 and the gap g of the C-shape shown in the plan view 153. Also, in Eq. (3), d_{PTFE} represents the spacing between the two C-shaped ring members 111 when polytetrafluoroethylene PTFE is used as the dielectric 112. Also, as shown in the cross-sectional view 152, it is preferable that the thicknesses d1 of the two C-shaped ring members 111 are the same.

In Eq. (5), the resonance frequency Fᵣ of the resonator 101 is obtained based on the inductance L_{MA} and the capacitance C_{MA} obtained from Eqs. (2) and (4). Also, the resonance frequency F, becomes lower as the outer radius rₒᵤₜ and the inner radius rᵢₙ of the C-shaped ring member 111 become larger and becomes lower as the thickness d of the dielectric 112 sandwiched between the two C-shaped ring members 111 becomes thinner. Also, the resonance frequency Fᵣ becomes lower as the number of stacked layers of the C-shaped ring members 111 increases. As will be described later, by adjusting the outer radius rₒᵤₜ and the inner radius rᵢₙ of the ring member 111 or the thickness d of the dielectric 112, resonators 101 having different resonance frequencies may be used. Moreover, in the present embodiment, a shape in which a cutout is provided in a portion of a circular ring is described as the C-shaped ring member 111, but the shape is not limited thereto. The shape of the ring member is not limited to a circular ring; for example, the ring member may have a shape in which a cutout (corresponding to the gap g) is provided in any one of an elliptical ring, a triangular ring, a rectangular ring, a polygonal ring, or the like.

In this manner, in the resonator array structure 100 of the present embodiment, since the plurality of resonators 101 are disposed in a direction facing the opening of the antenna 56, the magnetic field H passes through the C-shaped ring members 111 of the resonators 101, thereby enabling magnetic field resonance. Accordingly, each resonator 101 of the resonator array structure 100 may resonate at the resonance frequency Fᵣ.

Referring back to FIG. 1, the control device 11 has a processor, a memory, and an input/output interface. Programs, process recipes, and the like are stored in the memory. The processor, by reading and executing a program from the memory, comprehensively controls each part of the apparatus main body 10 through the input/output interface based on the process recipe stored in the memory.

The control device 11 controls the electromagnetic waves supplied to the processing space by the antenna 56 and the plurality of resonators 101 to resonate in a target frequency band higher than the resonance frequency of the plurality of resonators 101, for example, when plasma is generated in the processing space. Here, the resonance frequency is, for example, a frequency at which a transmission characteristic value (e.g., S21 value) of the plurality of resonators 101 becomes a local minimum value.

When the frequency of the electromagnetic waves supplied to the processing space by the antenna 56 matches the resonance frequency Fᵣ (e.g., about 2.35 GHZ) of the plurality of resonators 101, the S21 value of the plurality of resonators 101 becomes a local minimum value, and resonance between the electromagnetic waves and the plurality of resonators 101 occurs. The resonance between the electromagnetic waves and the plurality of resonators 101 is maintained even in a predetermined frequency band (e.g., about 0.1 GHZ) higher than the resonance frequency Fᵣ of the plurality of resonators 101. In the predetermined frequency band higher than the resonance frequency Fᵣ of the plurality of resonators 101, both the permittivity and permeability of the processing space may be made to have negative values due to the resonance between the electromagnetic waves and the plurality of resonators 101, and as may be understood from Eq. (1) above, electromagnetic waves are allowed to propagate in the processing space. The target frequency band of the present embodiment is set to a predetermined frequency band (e.g., about 0.1 GHZ) higher than the resonance frequency Fᵣ of the plurality of resonators 101. It is preferable that the target frequency band be, for example, within 0.05 times the resonance frequency Fᵣ of the plurality of resonators 101.

Also, the relationship between the resonance frequency and the refractive index, permittivity, and permeability regarding the propagation of electromagnetic waves through a plurality of resonators has been reported by D. R. Smith, D. C. Vier, Th. Koschny, and C. M. Soukoulis in “Electromagnetic parameter retrieval from inhomogeneous metamaterials,” PHYSICAL REVIEW E 71, 036617 (2005).

Next, a plasma processing method performed using the plasma processing apparatus 1 will be described. Here, as an example of plasma processing, a case in which a silicon nitride film is formed on the surface of the substrate W by plasma Chemical Vapor Deposition (CVD) will be described. First, the control device 11 controls the apparatus main body 10 to raise the wafer boat 20, on which a large number (e.g., 50) of substrates W of 300 mm size at room temperature are mounted, from below and load the wafer boat 20 into the processing container 12 adjusted to a predetermined temperature in advance. Thereafter, the control device 11 controls the apparatus main body 10 to hermetically seal the inside of the container by closing the lower end opening of the manifold 16 using the cover 26. While reducing the pressure inside the processing container 12 to maintain it at predetermined process pressure, the control device 11 controls the apparatus main body 10 to maintain the process temperature by increasing the power supplied to the heater 70 to raise the substrate temperature. The control device 11 controls the apparatus main body 10 to form a silicon nitride film on the surface of the substrate W supported by the rotating wafer boat 20 by alternately and intermittently supplying various processing gases from the gas suppliers 38 and 40, respectively.

Specifically, NH₃ gas is injected in a horizontal direction from each gas injection hole 42A of the plasma gas distribution nozzle 42 provided in the plasma generator 48. Also, HCD gas, which is a film-forming gas, is injected in a horizontal direction from each gas injection hole 44A of the film-forming gas distribution nozzle 44. The two injected gases react to form a silicon nitride film. At this time, a source RF signal from the RF power source 130 is being supplied to the antenna 56. Therefore, the NH₃ gas injected from the gas injection holes 44A flows into the resonator array structure 100 and is plasmatized and activated to generate radicals (active species) such as N*, NH*, NH₂*, and NH₃* (the symbol * indicates a radical). The generated radicals are discharged and diffused from the opening 52 of the plasma generator 48 toward the center of the processing container 12 and flow between the substrates W in a layer flow state. Then, each radical reacts with the molecules of the HCD gas attached to the surface of the substrate W to form the silicon nitride film as described above.

As described above, by causing electromagnetic waves and the plurality of resonators 101 to resonate in a target frequency band higher than the resonance frequency Fᵣ of the plurality of resonators 101, the electromagnetic waves are allowed to propagate beyond the skin depth of the plasma even when the electron density of the plasma reaches the cutoff density. For this reason, the power of the electromagnetic waves may be efficiently absorbed into the plasma. As a result, high-density plasma may be generated over a wide range beyond the skin depth of the plasma. In other words, according to the plasma processing apparatus 1 of the present embodiment, plasma may be highly densified over a wide range by causing the electromagnetic waves and the plurality of resonators 101 to resonate in a target frequency band higher than the resonance frequency Fᵣ of the plurality of resonators 101. Also, in the plasma processing apparatus 1 of the present embodiment, high-density plasma may be realized even in a so-called batch-type plasma processing apparatus by employing non-contact power feeding from the antenna 56 to the resonator array structure 100 within the processing container 12. In other words, the processing rate may be improved.

### (Modifications 1 to 4)

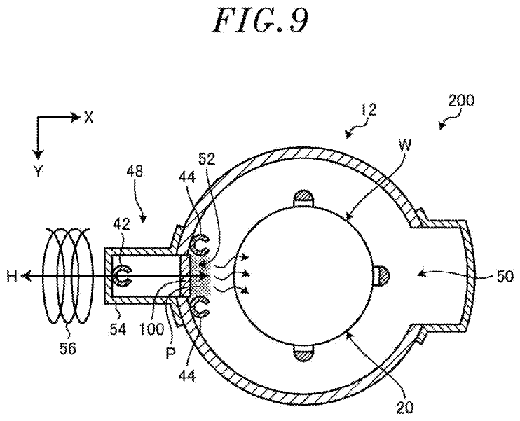

Next, Modifications 1 to 4 of the first embodiment will be described with reference to FIGS. 9 to 13. Modifications 1 to 4 are modifications of the arrangement of the resonator array structure 100. In the plasma processing apparatus 1 according to Modifications 1 to 4, at least one of the size and arrangement of the resonator array structure 100 and the shape of the processing container 12 on the antenna 56 side is appropriately changed. Therefore, in Modifications 1 to 4, descriptions of configurations and operations that overlap with those of the first embodiment described above will be omitted.

FIG. 9 is a schematic horizontal cross-sectional view illustrating an exemplary configuration of a plasma processing apparatus according to Modification 1. In an arrangement example 200 of Modification 1 shown in FIG. 9, the arrangement of the resonator array structure 100 of the first embodiment is moved to the opening 52 of the processing container 12 in the internal space of the plasma generator 48. In other words, the resonator array structure 100 of the arrangement example 200 is disposed closer to the center side of the processing container 12 than the position of the resonator array structure 100 of the first embodiment. In other words, in the Modification 1, the wafer boat 20 side of the resonator array structure 100 is located at the opening 52 of the processing container 12, and plasma P is generated between the two film-forming gas distribution nozzles 44. Also, the direction of the magnetic field H from the antenna 56 is the X-axis direction as in the first embodiment, which is a direction perpendicularly passing through the plane of the resonator array structure 100 from the plasma gas distribution nozzle 42 side of the plasma generator 48.

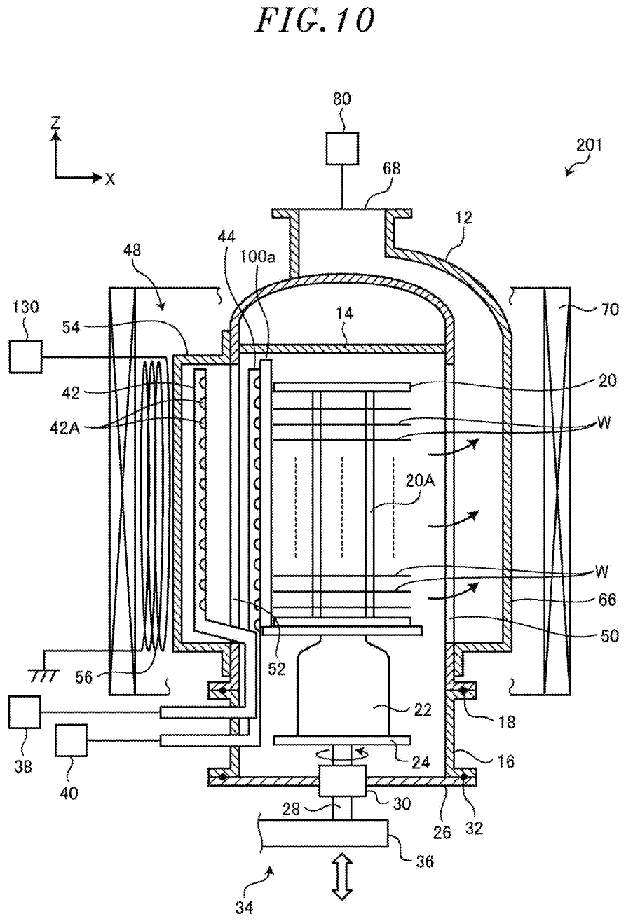

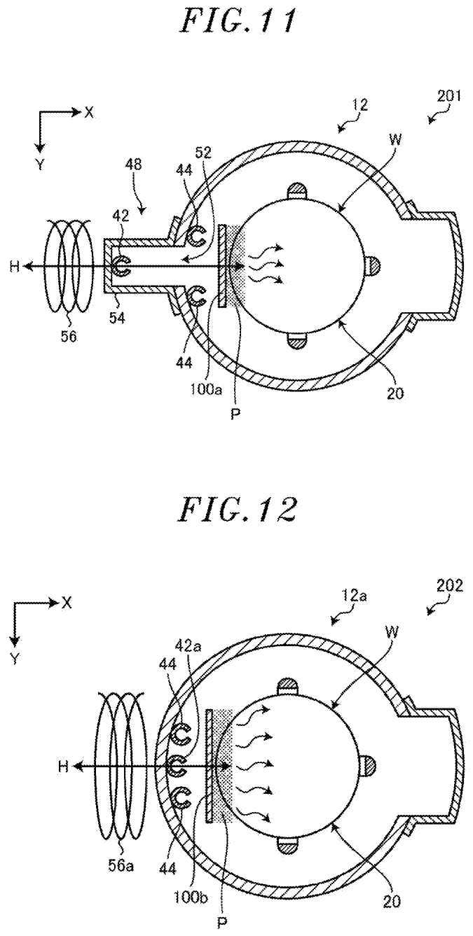

FIG. 10 is a schematic vertical cross-sectional view illustrating an exemplary configuration of a plasma processing apparatus according to Modification 2. FIG. 11 is a schematic horizontal cross-sectional view illustrating an exemplary configuration of a plasma processing apparatus according to the Modification 2. In an arrangement example 201 of Modification 2 shown in FIGS. 10 and 11, the arrangement of the resonator array structure 100 of the first embodiment is moved closer to the wafer boat 20 side than the opening 52 of the processing container 12, and the horizontal size is increased to form a resonator array structure 100a. In other words, the resonator array structure 100a is located within the cylinder of the processing container 12 rather than in the internal space of the plasma generator 48 and is disposed closer to the wafer boat 20 side than the two film-forming gas distribution nozzles 44. In other words, in Modification 2, as shown in FIG. 11, plasma P is generated on the wafer boat 20 side of the resonator array structure 100a. Also, the direction of the magnetic field H from the antenna 56 is the X-axis direction as in the first embodiment, which is a direction perpendicularly passing through the plane of the resonator array structure 100a through the opening 52 from the plasma gas distribution nozzle 42 side of the plasma generator 48.

FIG. 12 is a schematic horizontal cross-sectional view illustrating an exemplary configuration of a plasma processing apparatus according to Modification 3. In an arrangement example 202 of Modification 3 shown in FIG. 12, the processing container 12 of Modification 2 is replaced with a processing container 12a in which the plasma generator 48 and the opening 52 are omitted, and the horizontal size of the resonator array structure 100a of Modification 2 is increased to form a resonator array structure 100b. In addition, on the sidewall of the processing container 12a, a plasma gas distribution nozzle 42a is disposed between two film-forming gas distribution nozzles 44. Furthermore, an antenna 56a, which is an enlargement of the antenna 56 of Modification 2 according to the horizontal size of the resonator array structure 100b, is disposed on the outside (outside the container) of the arrangement position of the plasma gas distribution nozzle 42a of the processing container 12a. In Modification 3, as shown in FIG. 12, plasma P is generated on the wafer boat 20 side of the resonator array structure 100b. Also, the direction of the magnetic field H from the antenna 56a is the X-axis direction as in the first embodiment, which is a direction perpendicularly passing through the plane of the resonator array structure 100b from the plasma gas distribution nozzle 42a side.

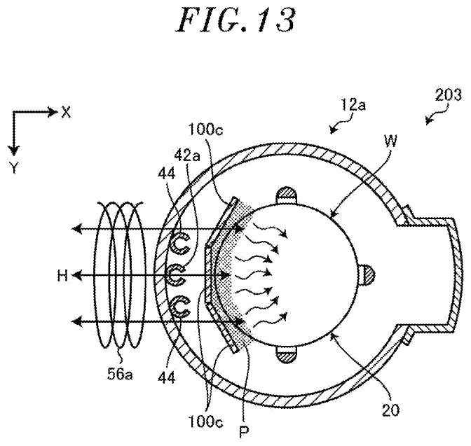

FIG. 13 is a schematic horizontal cross-sectional view illustrating an exemplary configuration of a plasma processing apparatus according to Modification 4. In an arrangement example 203 of Modification 4 shown in FIG. 13, the resonator array structure 100b of Modification 3 is replaced with a plurality of resonator array structures 100c, which have a horizontal size smaller than that of the resonator array structure 100b and are arranged to follow the outer periphery of the substrate W held in the wafer boat 20. For example, three resonator array structures 100c are arranged as shown in FIG. 13. The direction of the magnetic field H from the antenna 56a is the X-axis direction as in the first embodiment, which is a direction perpendicularly passing through the plane of the central resonator array structure 100c from the plasma gas distribution nozzle 42a side. At this time, for the resonator array structures 100c arranged on both sides, the direction of the magnetic field H passes obliquely through the plane of the resonator array structures 100c; however, since the magnetic field H includes a component passing perpendicularly through the plane of the resonator array structures 100c, each resonator 101 may still be allowed to resonate. Accordingly, as shown in FIG. 13, plasma P is generated on the wafer boat 20 side of each resonator array structure 100c. As shown in the resonator array structures 100 and 100a to 100c, the arrangement of the resonator array structure may have a degree of freedom with respect to the substrate W.

### (Modification 5)

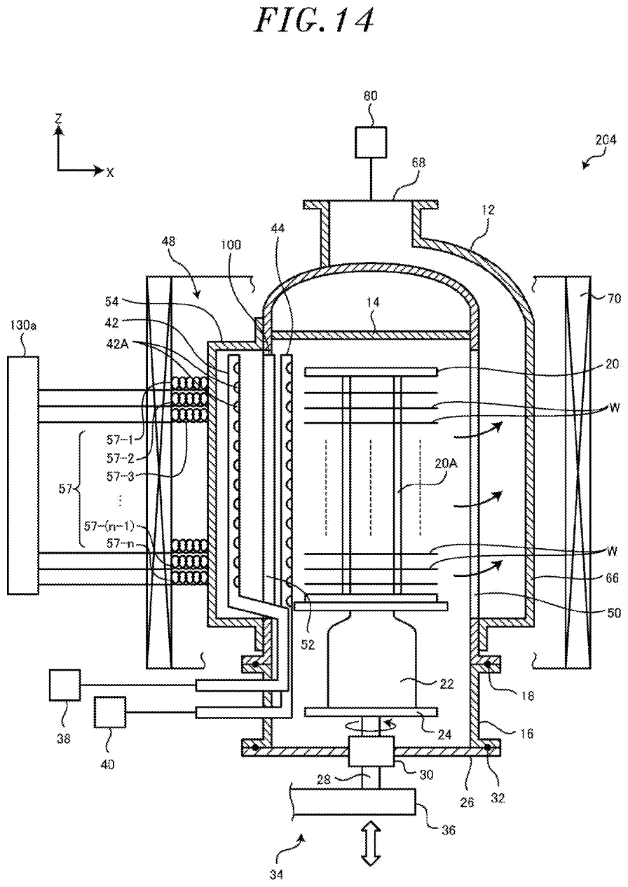

Subsequently, Modification 5 of the first embodiment will be described with reference to FIG. 14. Modification 5 is a modification of the antenna 56. In Modification 5, an antenna 57 and an RF power source 130a are provided instead of the antenna 56 and the RF power source 130 of the first embodiment. Therefore, in Modification 5, descriptions of configurations and operations that overlap with those of the first embodiment described above will be omitted.

FIG. 14 is a schematic vertical cross-sectional view illustrating an exemplary configuration of a plasma processing apparatus according to Modification 5. Modification 5 shown in FIG. 14 includes an antenna 57 and an RF power source 130a instead of the antenna 56 and the RF power source 130 of the first embodiment.

The antenna 57 includes a plurality of coils 57-1 to 57-n. Each of the coils 57-1 to 57-n is, for example, wound in a loop shape. The openings of the coils 57-1 to 57-n may have any shape such as a circle, an ellipse, or a polygon (e.g., a quadrilateral or a triangle). The openings of the coils 57-1 to 57-n face the center side (X-axis direction) of the processing container 12. The RF power source 130a is connected to the coils 57-1 to 57-n, and source RF signals are supplied thereto. Each magnetic field H generated by the coils 57-1 to 57-n is in the direction of the X-axis shown in FIG. 14.

The coils 57-1 to 57-n correspond to, for example, slots SL(1) to SL(n) shown in FIG. 3 and supply each magnetic field H (electromagnetic wave) to two rows of the arrangement of resonators 101 corresponding to the slots SL(1) to SL(n) of the resonator array structure 100.

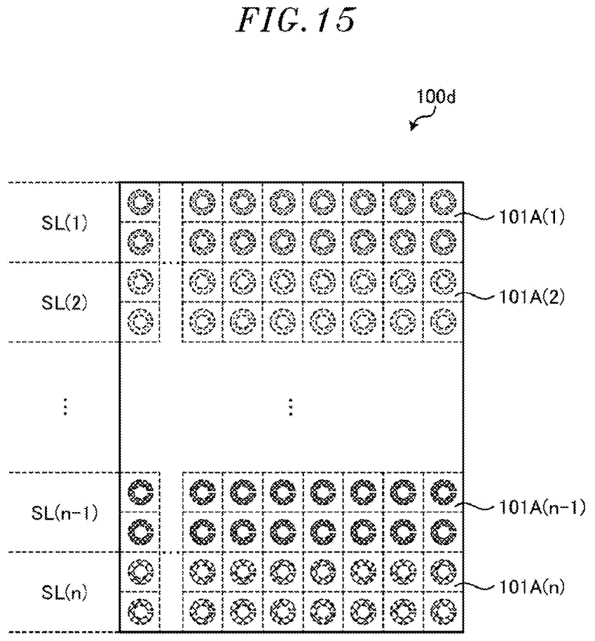

The RF power source 130a is coupled to the coils 57-1 to 57-n of the antenna 57, each of which is configured to generate a source RF signal (source RF power) for plasma generation through at least one impedance matching circuit. The RF power source 130a may individually supply source RF signals to each of the coils 57-1 to 57-n. The RF power source 130a generates and supplies source RF signals of different frequencies for each of the coils 57-1 to 57-n. In this case, the resonator array structure 100 changes the resonance frequency of the resonators 101 every two rows of the arrangement of resonators 101 corresponding to the slots SL(1) to SL(n), similarly to a resonator array structure 100d shown in FIG. 15 of Modification 6 described later. In other words, the antenna 57 and the RF power source 130a of Modification 5 are combined with the resonator array structure 100d of Modification 6 described later. In this manner, by changing the source RF signal supplied to each of the coils 57-1 to 57-n, the plasma density (processing rate) among the plurality of substrates W may be arbitrarily controlled.

### (Modifications 6 to 8)

Next, Modifications 6 to 8 of the first embodiment will be described with reference to FIGS. 15 to 17. Modifications 6 to 8 are modifications of the resonator array structure 100. In Modifications 6 to 8, resonator array structures 100d to 100f are provided, respectively, instead of the resonator array structure 100 of the first embodiment. Therefore, in Modifications 6 to 8, descriptions of configurations and operations that overlap with those of the first embodiment described above will be omitted.

FIG. 15 illustrates an exemplary configuration of a resonator array structure according to Modification 6. The resonator array structure 100d of Modification 6 shown in FIG. 15 includes resonators 101A(1) to 101A(n) in which the resonance frequency is changed every two rows of the arrangement of resonators 101A corresponding to the slots SL(1) to SL(n). In other words, the resonator 101A(1) corresponding to the slot SL(1) has a resonance frequency Fᵣ(1) and receives, for example, a source RF signal of an output frequency Fₒ(1) from the coil 57-1 of Modification 5. Similarly, the resonator 101A(2) corresponding to the slot SL(2) has a resonance frequency Fᵣ(2) and receives, for example, a source RF signal of an output frequency Fₒ(2) from the coil 57-2 of Modification 5. In what follows, similarly to the above, the resonator 101A(n) corresponding to the slot SL(n) has a resonance frequency Fᵣ(n) and receives, for example, a source RF signal of an output frequency Fₒ(n) from the coil 57-n of Modification 5. Also, the resonator array structure 100d may be configured to be divided every two rows of the arrangement of resonators 101A corresponding to the slots SL(1) to SL(n). As described above, in Modifications 5 and 6, the plasma density (processing rate) among the plurality of substrates W may be arbitrarily controlled.

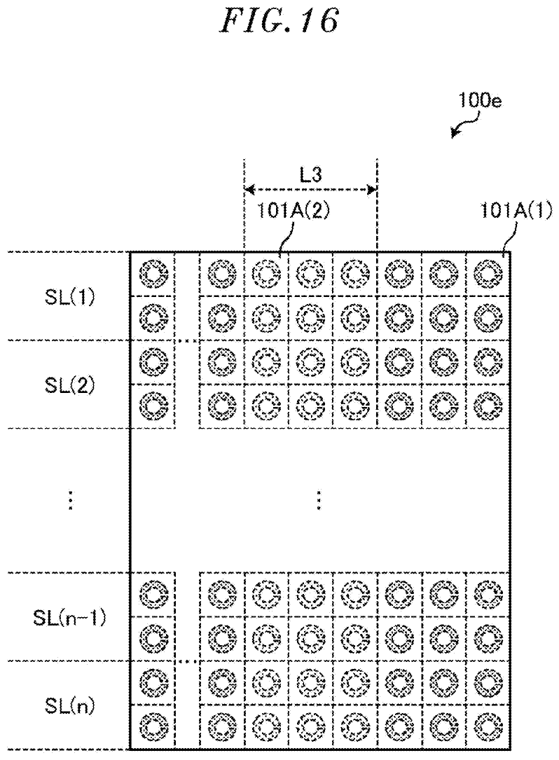

FIG. 16 illustrates an exemplary configuration of a resonator array structure according to Modification 7. In the resonator array structure 100e of Modification 7 shown in FIG. 16, resonators 101A(1) and 101A(2) having different resonance frequencies are arranged in a column corresponding to the outer peripheral portion and a column corresponding to the central portion of the substrate W held in the wafer boat 20, respectively. For example, the resonator 101A(2) is arranged in the column corresponding to L3 shown in FIG. 16, and the resonator 101A(1) is arranged in other columns. In this case, the resonator 101A(1) has a resonance frequency Fᵣ(1) and receives a source RF signal of an output frequency Fₒ(1). Furthermore, the resonator 101A(2) has a resonance frequency Fᵣ (2) and receives a source RF signal of an output frequency Fₒ(2). In Modification 7, the plasma density (processing rate) of the outer peripheral portion and the central portion may be controlled to be the same for each substrate W held in each of the slots SL(1) to SL(n) of the wafer boat 20.

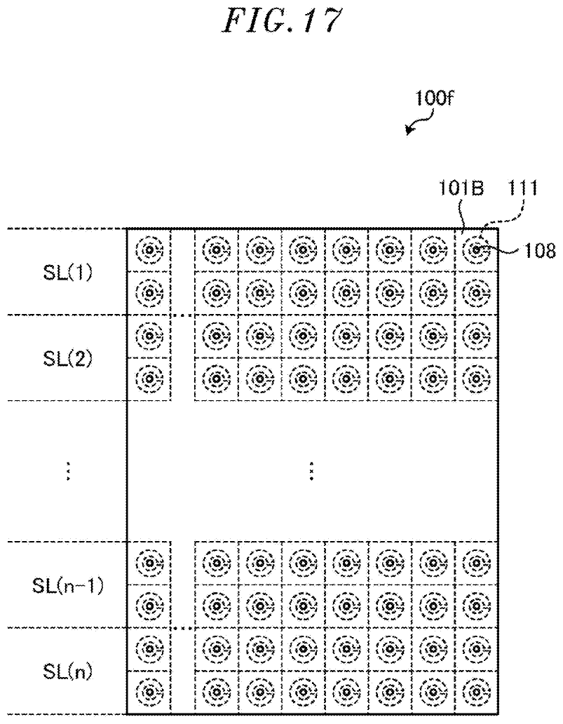

FIG. 17 illustrates an exemplary configuration of a resonator array structure according to Modification 8. In the resonator array structure 100f of Modification 8 shown in FIG. 17, a through-hole 108 is provided in each of a plurality of resonators 101B arranged in a lattice shape. The through-hole 108 is provided at the center of the resonator 101B and is formed to penetrate the dielectric 112 through the center of the two C-shaped ring members 111. In other words, the through-hole 108 penetrates the first surface 106 and the second surface 107 of the resonator array structure 100f. In the example of FIG. 17, 2n rows of resonators 101B are arranged in the row direction so as to correspond to the slots SL(1) to SL(n) of the wafer boat 20, respectively. In other words, in the resonator array structure 100f of Modification 8, gas to be plasmatized injected from the gas injection holes 42A of the plasma gas distribution nozzle 42 may flow more easily toward the center of the processing container 12.

### Second Embodiment

In the first embodiment described above, the flat-plate-shaped resonator array structure 100 in which a plurality of resonators 101 are arranged on the same plane was used; however, a resonator array structure in which the resonators 101 are arranged perpendicularly to a flat-plate-shaped base plate may also be used. An embodiment using such a resonator array structure will be described as the second embodiment. Furthermore, since the plasma processing apparatus in the second embodiment is the same as that of the first embodiment described above except for the configuration of the resonator array structure and the arrangement of the antenna, descriptions of overlapping configurations and operations will be omitted.

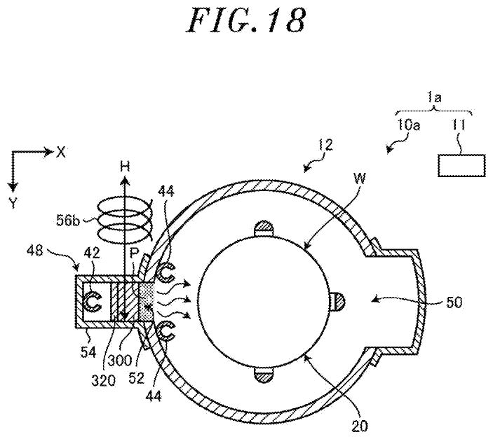

FIG. 18 is a schematic horizontal cross-sectional view illustrating an exemplary configuration of a plasma processing apparatus according to a second embodiment. As shown in FIG. 18, the apparatus main body 10a of the plasma processing apparatus 1a of the second embodiment has a resonator array structure 300 different from the resonator array structure 100 of the first embodiment. Also, an antenna 56b is disposed outside the plasma partition wall 54 (outside the processing container 12) on the side surface of the plasma generator 48.

The resonator array structure 300 is formed by arranging a plurality of resonators that are capable of resonating with the magnetic field component of electromagnetic waves and have a size smaller than the wavelength of the electromagnetic waves, and is located in a region within the processing container 12 in which the electromagnetic waves may be supplied through the plasma partition wall 54. The corresponding region is, for example, the internal space of the plasma generator 48. The resonator array structure 300 is arranged such that the base plate 320 faces toward the end side of the plasma generator 48 (the plasma gas distribution nozzle 42 side). The magnetic field H generated by the antenna 56b is in a direction (Y-axis direction) that penetrates the resonators 301 of a cell CS, which will be described later, from the side surface of the resonator array structure 300.

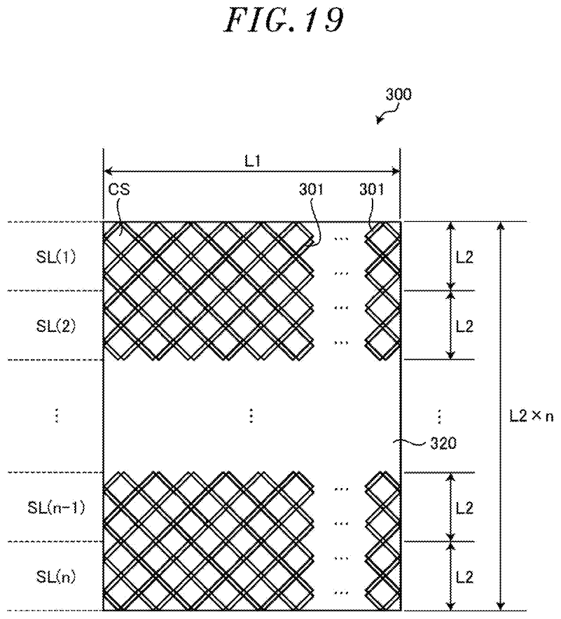

Here, a detailed configuration of a resonator array structure 300 will be described with reference to FIG. 19. FIG. 19 illustrates an exemplary configuration of a resonator array structure according to the second embodiment. FIG. 19 shows the resonator array structure 300 as viewed from the wafer boat 20 side in the X-axis direction of FIG. 18. The resonator array structure 300 is formed to be sufficiently long in a vertical direction, thereby covering all substrates W held in the wafer boat 20 in a height direction.

As shown in FIG. 18, the resonator array structure 300 is disposed in the internal space of the plasma generator 48. In the present embodiment, plasma P is generated on the wafer boat 20 side of the resonator array structure 300 in the internal space of the plasma generator 48. Although FIG. 18 illustrates the plasma P closer to the center side of the processing container 12 than the resonator array structure 300, the plasma P is actually generated in the space within the cell CS, which will be described later.

The resonator array structure 300 is arranged such that a plurality of resonators 301 that are capable of resonating with the magnetic field component of microwaves and have a size smaller than the wavelength of the microwaves form a plurality of cells CS. In the resonator array structure 300, the plurality of resonators 301 are arranged perpendicularly to the flat-plate-shaped base plate 320 to form the plurality of cells CS. In other words, the plurality of resonators 301 are disposed on a plane perpendicular to the longitudinal surface of the resonator array structure 300. The plurality of cells CS are arranged in a diamond shape in each of a row direction and a column direction, for example, by arranging the plurality of resonators 301 in a lattice shape and rotating the arrangement by 45 degrees. Each cell CS is surrounded by resonators 301 having the same resonance frequency. Also, since the resonance frequency of the resonator 301 is the same as that of the resonator 101 of the first embodiment, the description thereof will be omitted. The opening of the cell CS faces the center side of the processing container 12 (the wafer boat 20 side). In other words, as shown in FIG. 18, the magnetic field H generated by the antenna 56b penetrates from the side surface of the cell CS, thereby enabling each resonator 301 of each cell CS to resonate due to the magnetic field H.

In the resonator array structure 300, for example, cells CS comprising a plurality of columns are arranged in a column direction (horizontal direction) according to the width of the internal space of the plasma generator 48, and cells CS comprising three rows are arranged per one slot SL for accommodating the substrate W in the wafer boat 20 in a row direction (vertical direction). Since the cells CS are diamond-shaped, in the end portions of left and right part of the resonator array structure 300, along the first column of cells CS where the diamond-shaped vertices contact the end surface of the base plate 320 and the second column of cells CS where the diamond-shaped vertices do not contact the end surface at the left and right ends of the resonator array structure 300 in a vertical direction, the second column of cells CS forms a staggered arrangement shifted in the horizontal direction. Similarly, in the end portions of upper and lower part of the resonator array structure 300, along the first row of cells CS where the diamond-shaped vertices contact the end surface and the second row of cells CS where the diamond-shaped vertices do not contact the end surface at the upper and lower ends of the resonator array structure 300 in a horizontal direction, the second row of cells CS forms a staggered arrangement shifted in the vertical direction. In the example of FIG. 19, when n substrates W are accommodated in the wafer boat 20, slots SL(1) to SL(n) are disposed, and 3n rows of cells CS are arranged in the row direction. In other words, the size of the resonator array structure 300 may be expressed as L1 in the column direction and L2×n in the row direction, where L1 is the width of the resonator array structure 300 in the column direction and L2 is the length of one slot SL in the row direction. Also, the direction of the magnetic field H is a column direction (a horizontal direction), which passes through each resonator 301 of the cell CS.

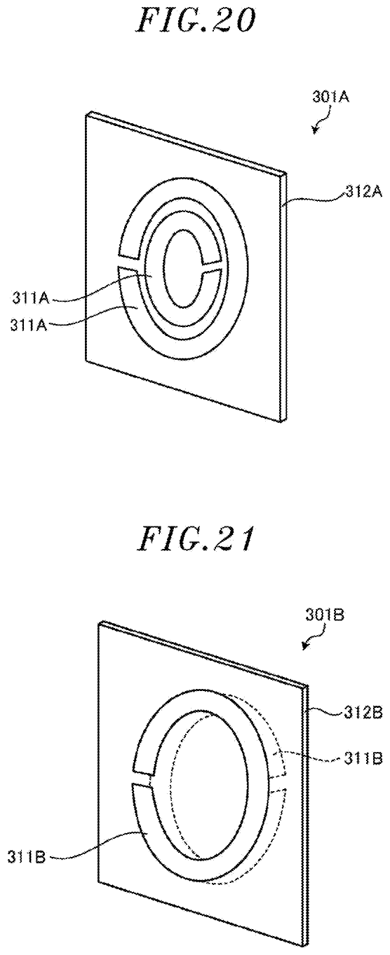

As an example of a specific configuration, the plurality of resonators 301 include at least one of a resonator 301A and a resonator 301B shown in FIGS. 20 and 21. Each of the plurality of resonators 301 constitutes a series resonance circuit composed of a capacitor equivalent element and a coil equivalent element. The series resonance circuit is realized by patterning a conductor on a plane.

FIG. 20 illustrates an exemplary configuration of a resonator according to the second embodiment. The resonator 301A shown in FIG. 20 has a structure in which two C-shaped ring members 311A made of a conductor, which are concentric and face opposite directions, are stacked on one surface of a dielectric plate 312A. Capacitor equivalent elements are formed at facing surfaces of the inner ring member 311A and the outer ring member 311A or at both ends of each ring member 311A, and a coil equivalent element is formed along each ring member 311A. Accordingly, the resonator 301A may constitute a series resonance circuit. Furthermore, the resonator 301A may still be applied to other embodiments or modifications such as the resonator 101 of the first embodiment.

FIG. 21 illustrates an exemplary configuration of a resonator according to the second embodiment. The resonator 301B shown in FIG. 21 has a structure in which a dielectric plate 312B is disposed between two C-shaped ring members 311B made of a conductor, which are disposed adjacent to each other in opposite directions. In other words, in the resonator 301B, the dielectric plate 312B is sandwiched between the two C-shaped ring members 311B facing opposite directions. Capacitor equivalent elements are formed at facing surfaces of the two C-shaped ring members 311B or at both ends of each ring member 311B, and a coil equivalent element is formed along each ring member 311B. Accordingly, the resonator 301B may constitute a series resonance circuit. It may also be stated that the resonator 301B is formed for each pair of the two C-shaped ring members 311B.

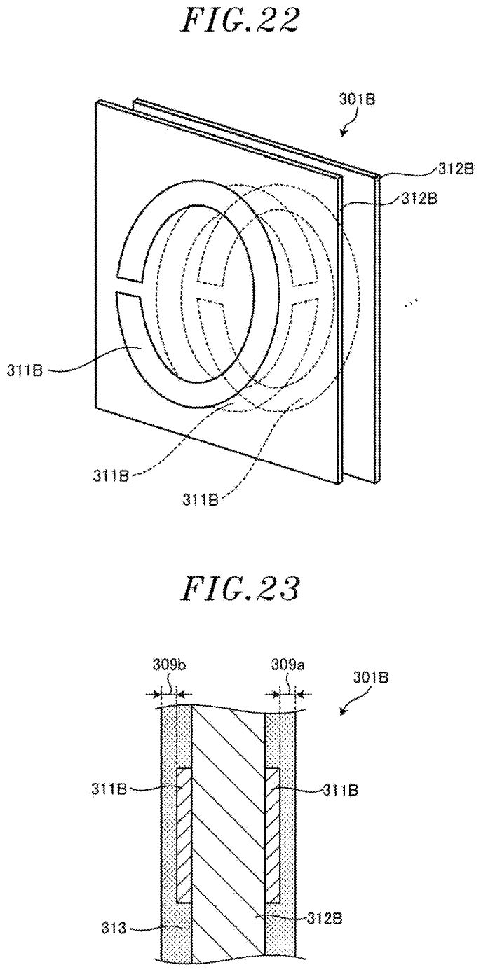

In the resonator 301B shown in FIG. 21, the number of ring members 311B arranged (hereinafter appropriately referred to as the “number of layers”) is two, but the number of layers of the ring members 311B may be greater than two. FIG. 22 illustrates another exemplary configuration of a resonator according to the second embodiment. The resonator 301B shown in FIG. 22 has a structure in which a dielectric plate 312B is disposed between N (N≥2) C-shaped ring members 311B made of a conductor, the C-shaped ring members 311B being arranged adjacent to each other in opposite directions. The example in FIG. 22 illustrates a case where three ring members 311B are stacked in the resonator 301B. Even with such a structure, the resonator 301B may still constitute a series resonance circuit. Furthermore, the resonator 301B may be applied to other embodiments or modifications, such as the resonator 101 of the first embodiment.

Also, an insulating film may be formed on each of the plurality of resonators 301. FIG. 23 shows an example of a cross-section of a resonator according to the second embodiment. FIG. 23 shows a side cross-section of the resonator 301B shown in FIG. 21. An insulating film (an example of a dielectric film) 313 is formed on the surface of the resonator 301B. The material of the film 313 is, for example, ceramic. The thickness of the film 313 is, for example, within a range of 0.001 mm to 2 mm. By forming the insulating film 313 on each of the plurality of resonators 301, abnormal discharge in each of the plurality of resonators 301 may be suppressed.

The film 313 may be formed such that a thickness 309a of the film 313 covering the first ring member 311B is thinner than a thickness 309b of the film 313 covering the second ring member 311B. In this case, plasma may be selectively generated on the side of the first ring member 311B covered with a thin film 313. For example, in the resonators 301 located at the outermost part of the resonator array structure 300, by arranging the resonators 301 so that their surface with a thin film 313 faces the inner side of the cell CS, plasma may be selectively generated on the inner side of the cell CS.

In the second embodiment, the cell-type resonator array structure 300 is disposed in the internal space of the plasma generator 48, and the antenna 56b is disposed outside the plasma partition wall 54 on the side surface of the plasma generator 48. In the second embodiment, by employing non-contact power feeding from the antenna 56b to the resonator array structure 300 within the processing container 12, high-densification of plasma may be realized even in a so-called batch-type plasma processing apparatus.

### (Modifications 9 to 12)

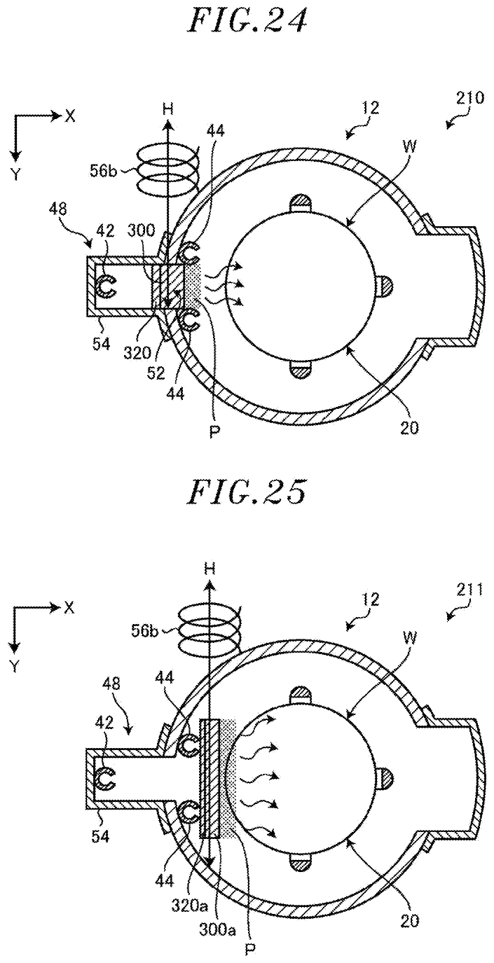

Next, Modifications 9 to 12 of the second embodiment will be described with reference to FIGS. 24 to 27. Modifications 9 to 12 are modifications of the arrangement of the resonator array structure 300. In the plasma processing apparatus 1a according to Modifications 9 to 12, at least one of the size and arrangement of the resonator array structure 300 and the shape of the processing container 12 on the plasma gas distribution nozzle 42 side is appropriately changed. Therefore, in Modifications 9 to 12, descriptions of configurations and operations that overlap with those of the first and second embodiments described above will be omitted. Also, Modifications 9 to 12 correspond to Modifications 1 to 4 of the first embodiment.

FIG. 24 is a schematic horizontal cross-sectional view illustrating an exemplary configuration of a plasma processing apparatus according to Modification 9. In an arrangement example 210 of Modification 9 shown in FIG. 24, the arrangement of the resonator array structure 300 of the second embodiment is moved to the opening 52 of the processing container 12 in the internal space of the plasma generator 48. In other words, the resonator array structure 300 of the arrangement example 210 is disposed closer to the center side of the processing container 12 than the position of the resonator array structure 300 of the second embodiment. In other words, in Modification 9, the wafer boat 20 side of the resonator array structure 300 is located closer to the wafer boat 20 than the opening 52 of the processing container 12, and plasma P is generated in the cells CS located between the two film-forming gas distribution nozzles 44. Also, the direction of the magnetic field H from the antenna 56b is the Y-axis direction as in the second embodiment, which is a direction substantially parallel to the base plate 320 of the resonator array structure 300.

FIG. 25 is a schematic horizontal cross-sectional view illustrating an exemplary configuration of a plasma processing apparatus according to Modification 10. In an arrangement example 211 of Modification 10 shown in FIG. 25, the arrangement of the resonator array structure 300 of the second embodiment is moved closer to the wafer boat 20 side than the opening 52 of the processing container 12, and the horizontal size of the resonator array structure 300 is increased to form a resonator array structure 300a. In other words, the resonator array structure 300a is located within the cylinder of the processing container 12 rather than in the internal space of the plasma generator 48 and is disposed closer to the wafer boat 20 side than the two film-forming gas distribution nozzles 44. In other words, in Modification 10, as shown in FIG. 25, plasma P is generated in the cells CS on the wafer boat 20 side of the resonator array structure 300a. Also, the direction of the magnetic field H from the antenna 56b is the Y-axis direction as in the second embodiment, which is a direction substantially parallel to the base plate 320a of the resonator array structure 300a.

FIG. 26 is a schematic horizontal cross-sectional view illustrating an exemplary configuration of a plasma processing apparatus according to Modification 11. An arrangement example 212 of Modification 11 shown in FIG. 26 uses a processing container 12a in which the plasma generator 48 and the opening 52 of Modification 10 are omitted. Furthermore, in the processing container 12a, a plasma gas distribution nozzle 42a is disposed between the two film-forming gas distribution nozzles 44 on the sidewall of the processing container 12a. In Modification 11, as shown in FIG. 26, plasma P is generated in the cells CS on the wafer boat 20 side of the resonator array structure 300a. Also, the direction of the magnetic field H from the antenna 56b is the Y-axis direction as in the second embodiment, which is a direction substantially parallel to the base plate 320a of the resonator array structure 300a.

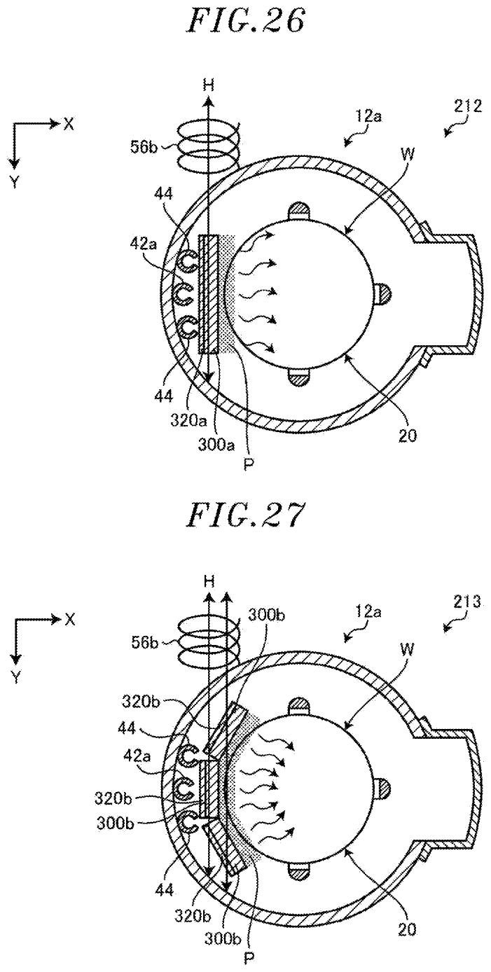

FIG. 27 is a schematic horizontal cross-sectional view illustrating an exemplary configuration of a plasma processing apparatus according to Modification 12. In an arrangement example 213 of Modification 12 shown in FIG. 27, the resonator array structure 300a of Modification 11 is replaced with a plurality of resonator array structures 300b having a horizontal size smaller than that of the resonator array structure 300a, and the plurality of resonator array structures 300b are arranged to follow the outer periphery of the substrate W held in the wafer boat 20. For example, three resonator array structures 300b are arranged as shown in FIG. 27. The direction of the magnetic field H from the antenna 56b is the Y-axis direction as in the second embodiment, which is a direction substantially parallel to the base plate 320b of the central resonator array structure 300b. At this time, for the resonator array structures 300b arranged on both sides, the direction of the magnetic field H passes obliquely through the resonators 301 of the cells CS, but each resonator 301 may still be allowed to resonate. Accordingly, as shown in FIG. 27, plasma P is generated in the cells CS on the wafer boat 20 side of each resonator array structure 300b. As shown in the resonator array structures 300 and 300a to 300b, the arrangement of the resonator array structure may have a degree of freedom with respect to the substrate W.

### (Modifications 13 and 14)

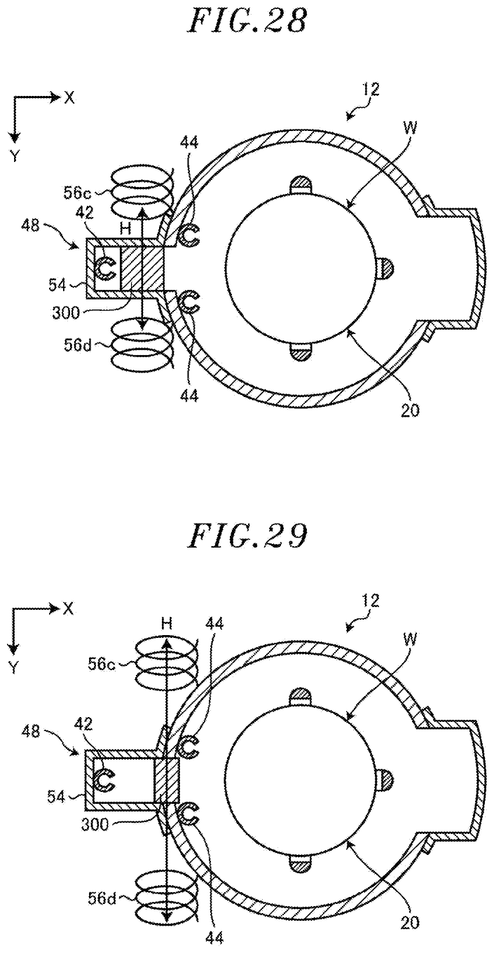

Subsequently, Modification 13 and 14 of the second embodiment will be described with reference to FIGS. 28 and 29. Modifications 13 and 14 are modifications of the antenna 56b. In Modifications 13 and 14, antennas 56c and 56d are provided instead of the antenna 56b of the second embodiment. Therefore, in Modifications 13 and 14, descriptions of configurations and operations that overlap with those of the first and second embodiments described above will be omitted.

FIG. 28 is a schematic horizontal cross-sectional view illustrating an exemplary configuration of a plasma processing apparatus according to Modification 13. FIG. 29 is a schematic horizontal cross-sectional view illustrating an exemplary configuration of a plasma processing apparatus according to Modification 14. Modification 13 shown in FIG. 28 and Modification 14 shown in FIG. 29 have antennas 56c and 56d instead of the antenna 56b of the second embodiment. Furthermore, the arrangement of the resonator array structure 300 of Modification 13 is the same as that of the second embodiment, and the arrangement of the resonator array structure 300 of Modification 14 is the same as that of Modification 9.

The antennas 56c and 56d are disposed being opposite each other outside the plasma partition wall 54 (outside the processing container 12) on the side surface of the plasma generator 48, with the plasma generator 48 interposed therebetween. Since each of the antennas 56c and 56d generates a magnetic field H, the magnetic field H penetrates from both sides of the resonator array structure 300 in the Y-axis direction. In contrast, in the antenna 56b of the second embodiment, since the magnetic field H penetrates from one side of the resonator array structure 300 in the Y-axis direction, the magnetic field H is absorbed by the resonators 301 of the cells CS closer to the antenna 56b, and the magnetic field H reaching the resonators 301 of distant cells CS is attenuated. In other words, plasma density varies in each cell CS of the resonator array structure 300. In Modifications 13 and 14, since the magnetic field H penetrates from both sides of the resonator array structure 300, the deviation of the magnetic field H in the Y-axis direction is reduced, thereby improving plasma uniformity.

### (Modifications 15 and 16)

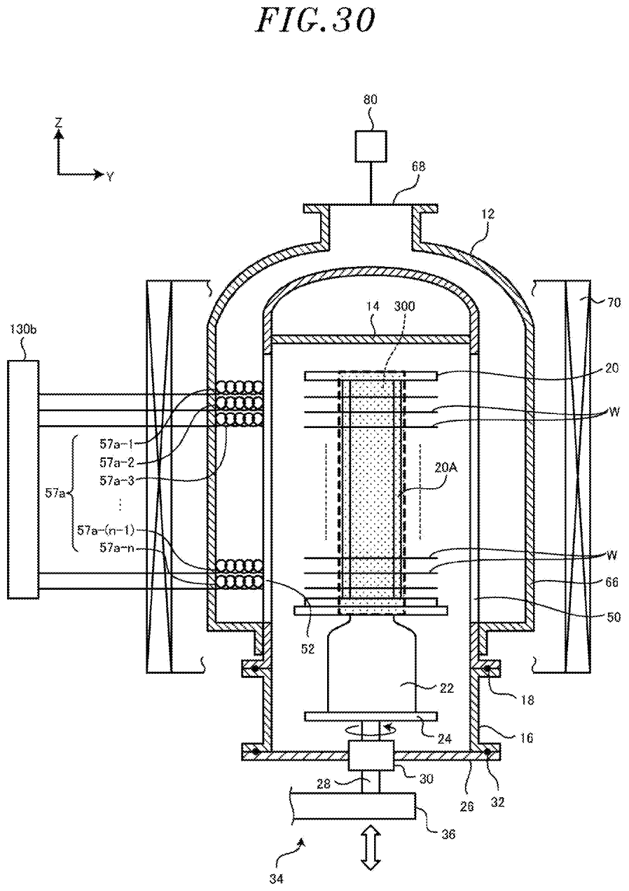

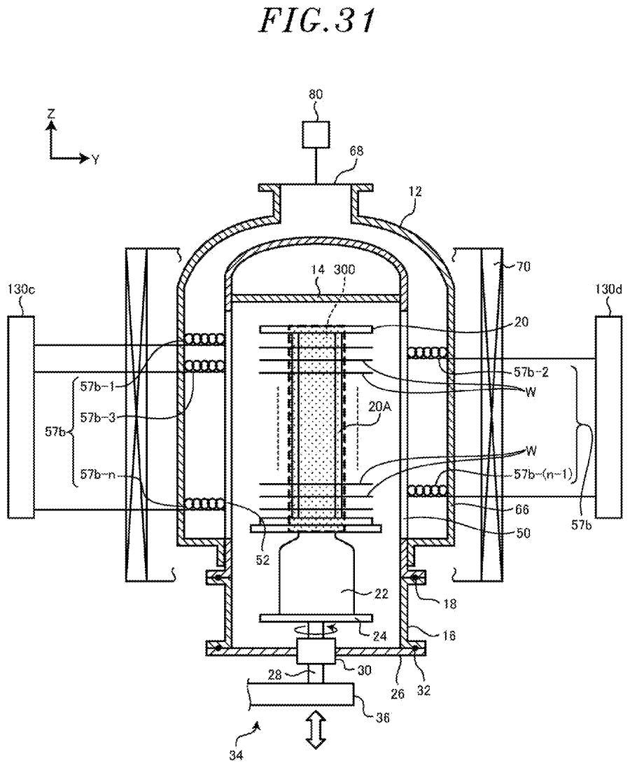

Next, Modifications 15 and 16 of the second embodiment will be described with reference to FIGS. 30 and 31. Modifications 15 and 16 are modifications of the antenna 56b. In Modification 15, an antenna 57a and an RF power source 130b are provided instead of the antenna 56b and the RF power source 130 of the second embodiment. Therefore, in Modification 15, descriptions of configurations and operations that overlap with those of the first and second embodiments described above will be omitted. Furthermore, Modification 15 corresponds to Modification 5 of the first embodiment.

FIG. 30 is a schematic vertical cross-sectional view illustrating an exemplary configuration of a plasma processing apparatus according to Modification 15. Modification 15 shown in FIG. 30 has an antenna 57a and an RF power source 130b instead of the antenna 56b and the RF power source 130 of the second embodiment.

Similarly to the case of antenna 56b, the antenna 57a is disposed outside the plasma partition wall 54 (outside the processing container 12) on the side surface of the plasma generator 48. The antenna 57a includes a plurality of coils 57a-1 to 57a-n. Each of the coils 57a-1 to 57a-n is, for example, wound in a loop shape. The openings of the coils 57a-1 to 57a-n may have any shape such as a circle, an ellipse, or a polygon (e.g., a quadrilateral or a triangle). The openings of the coils 57a-1 to 57a-n face the side surface (Y-axis direction) of the resonator array structure 300 disposed in the internal space of the plasma generator 48. The RF power source 130b is connected to the coils 57a-1 to 57a-n, and source RF signals are supplied to the coils 57a-1 to 57a-n. Each magnetic field H generated by the coils 57a-1 to 57a-n is in the Y-axis direction shown in FIG. 30.

The coils 57a-1 to 57a-n correspond to, for example, the slots SL(1) to SL(n) shown in FIG. 19 and supply magnetic field H (electromagnetic wave) to three rows of the arrangement of resonators 301 corresponding to the slots SL(1) to SL(n) of the resonator array structure 300.

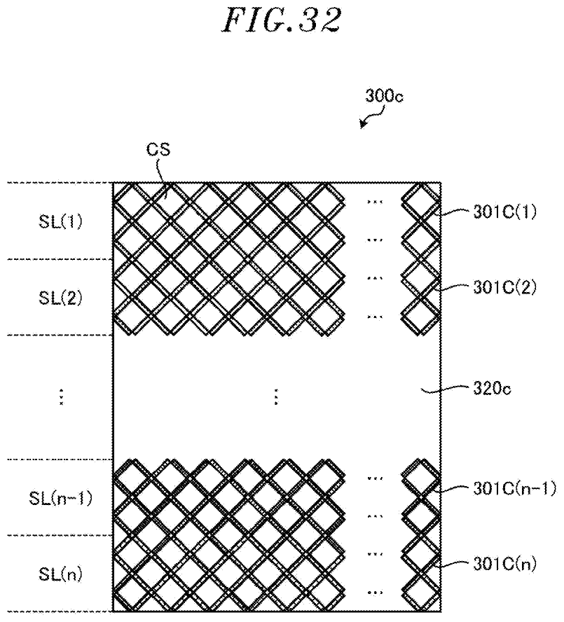

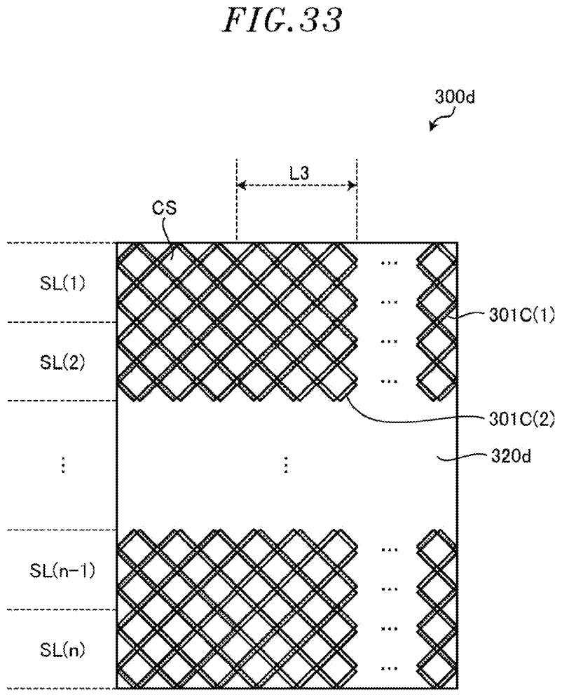

The RF power source 130b is coupled to the coils 57a-1 to 57a-n of the antenna 57a, each of which is configured to generate a source RF signal (source RF power) for plasma generation through at least one impedance matching circuit. The RF power source 130b may individually supply source RF signals to each of the coils 57a-1 to 57a-n. The RF power source 130b generates source RF signals of different frequencies for each of the coils 57a-1 to 57a-n. In this case, the resonator array structure 300 changes the resonance frequency of the resonators 301 every three rows of the arrangement of resonators 301 corresponding to the slots SL(1) to SL(n), similarly to a resonator array structure 300c shown in FIG. 32 of Modification 17 described later. In other words, the antenna 57a and the RF power source 130b of Modification 15 are combined with the resonator array structure 300c of Modification 17 described later. In this manner, by changing the source RF signal supplied to each of the coils 57a-1 to 57a-n, the plasma density (processing rate) among the plurality of substrates W may be arbitrarily controlled.

FIG. 31 is a schematic vertical cross-sectional view illustrating an exemplary configuration of a plasma processing apparatus according to Modification 16. In Modification 16, an antenna 57b and RF power sources 130c and 130d are provided instead of the antenna 56b and the RF power source 130 of the second embodiment. Therefore, in Modification 16, descriptions of configurations and operations that overlap with those of the first and second embodiments described above will be omitted.

Modification 16 shown in FIG. 31 has an antenna 57b and RF power sources 130c and 130d instead of the antenna 56b and the RF power source 130 of the second embodiment. In Modification 16, the coils 57a-1 to 57a-n of the antenna 57a of Modification 15 are alternately arranged in a staggered manner with the plasma generator 48 interposed therebetween, similarly to cases of antennas 56c and 56d of Modification 14.

Similarly to cases of the antennas 56c and 56d, the antenna 57b is disposed outside the plasma partition wall 54 (outside the processing container 12) on the side surface of the plasma generator 48. The antenna 57b has a plurality of coils 57b-1 to 57b-n. Each of the coils 57b-1 to 57b-n is wound in a loop shape. The openings of the coils 57b-1 to 57b-n may have any shape such as a circle, an ellipse, or a polygon (e.g., a quadrilateral or a triangle). The openings of the coils 57b-1 to 57b-n face the side surface (Y-axis direction) of the resonator array structure 300 disposed in the internal space of the plasma generator 48. For example, coils 57b-1, 57b-3, . . . , 57b-n are disposed on the left side of the processing container 12 in FIG. 31, and coils 57b-2, 57b-4, . . . , 57b-(n−1) are disposed on the right side of the processing container 12. The RF power source 130c is connected to the coils 57b-1, 57b-3, . . . , 57b-n, and source RF signals are supplied to the coils 57b-1, 57b-3, . . . , 57b-n. The RF power source 130d is connected to the coils 57b-2, 57b-4, . . . , 57b-(n−1), and source RF signals are supplied to the coils 57b-2, 57b-4, . . . , 57b-(n−1). The RF power sources 130c and 130d are obtained by dividing the RF power source 130b according to the arrangement of the coils 57b-1 to 57b-n. Also, the RF power sources 130c and 130d may be replaced with one RF power source 130b. Each magnetic field H generated by the coils 57b-1 to 57b-n is in the Y-axis direction shown in FIG. 31.

### (Modifications 17 to 20)

Next, Modifications 17 to 20 of the second embodiment will be described with reference to FIGS. 32 to 35. Modifications 17 to 20 are modifications of the resonator array structure 300. In Modifications 17 to 20, resonator array structures 300c to 300f are provided respectively instead of the resonator array structure 300 of the second embodiment. Therefore, in Modifications 17 to 20, descriptions of configurations that overlap with those of the second embodiment described above will be omitted.

FIG. 32 illustrates an exemplary configuration of a resonator array structure according to Modification 17. The resonator array structure 300c of Modification 17 shown in FIG. 32 includes resonators 301C(1) to 301C(n) in which the resonance frequency is changed every three rows of the arrangement of cells CS corresponding to the slots SL(1) to SL(n). In other words, the resonator 301C(1) of a cell CS corresponding to the slot SL(1) has a resonance frequency Fᵣ(1) and receives, for example, a source RF signal of an output frequency Fₒ(1) from the coil 57a-1 of Modification 15. Similarly, the resonator 301C(2) of a cell CS corresponding to the slot SL(2) has a resonance frequency F, (2) and receives, for example, a source RF signal of an output frequency F. (2) from the coil 57a-2 of Modification 15. In what follows, similarly to the above, the resonator 301C(n) of a cell CS corresponding to the slot SL(n) has a resonance frequency Fᵣ(n) and receives, for example, a source RF signal of an output frequency Fₒ(n) from the coil 57a-n of Modification 15. Also, the resonator array structure 300c may be configured to be divided every three rows of the arrangement of cells CS corresponding to the slots SL(1) to SL(n). As described above, in Modifications 15 and 17, the plasma density (processing rate) among the plurality of substrates W may be arbitrarily controlled.

FIG. 33 illustrates an exemplary configuration of a resonator array structure according to Modification 18. In the resonator array structure 300d of Modification 18 shown in FIG. 33, cells CS comprising resonators 301C(1) and 301C(2) having different resonance frequencies are arranged in a column corresponding to the outer peripheral portion and a column corresponding to the central portion of the substrate W held in the wafer boat 20, respectively. The resonators 301C(1) and 301C(2) are arranged on the base plate 320d to form the cells CS. For example, cells CS comprising resonators 301C(2) are arranged in the column corresponding to L3 shown in FIG. 33, and cells CS comprising resonators 301C(1) are arranged in other columns. In this case, the resonator 301C(1) has a resonance frequency Fᵣ(1) and receives a source RF signal of an output frequency Fₒ(1). Furthermore, the resonator 301C(2) has a resonance frequency Fᵣ(2) and receives a source RF signal of an output frequency Fₒ(2). In Modification 18, the plasma density (processing rate) of the outer peripheral portion and the central portion may be controlled to be the same for each substrate W held in each of the slots SL(1) to SL(n) of the wafer boat 20.

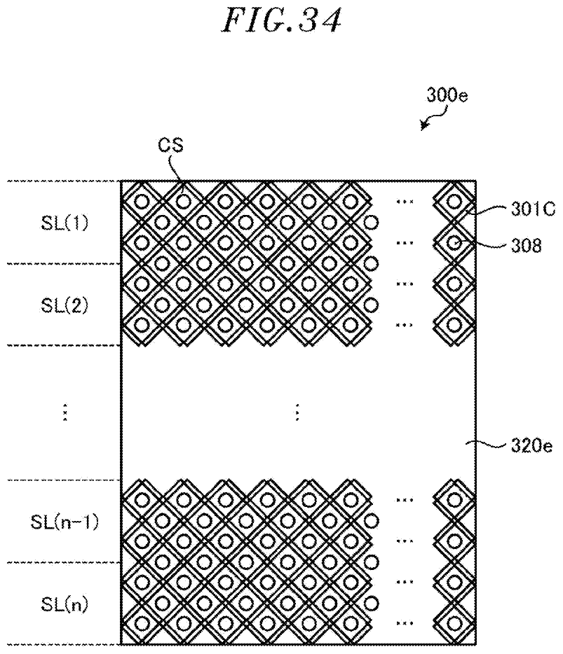

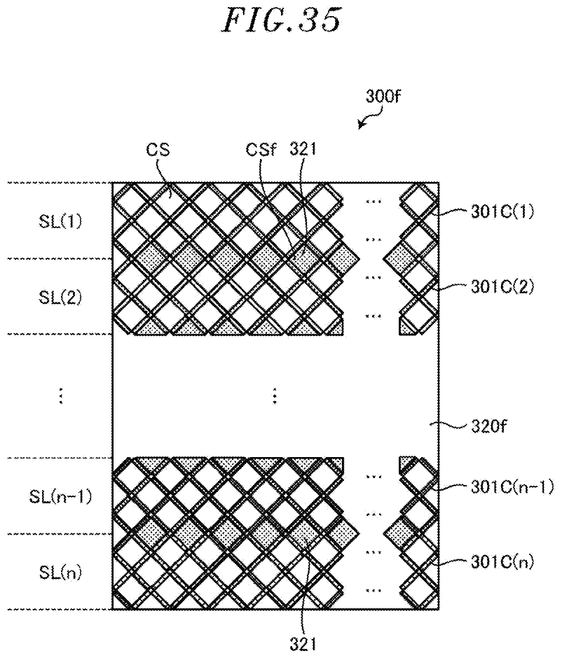

FIG. 34 illustrates an exemplary configuration of a resonator array structure according to Modification 19. In the resonator array structure 300e of Modification 19 shown in FIG. 34, a through-hole 308 is provided in each of a plurality of cells CS arranged in a lattice shape. The through-hole 308 is provided at the center of the cell CS and is formed to penetrate the base plate 320c. In the example of FIG. 34, 3n rows of cells CS are arranged in the row direction to correspond to the slots SL(1) to SL(n) of the wafer boat 20, respectively. In other words, in the resonator array structure 300e of Modification 19, gas to be plasmatized injected from the gas injection holes 42A of the plasma gas distribution nozzle 42 may flow more easily toward the center of the processing container 12.

FIG. 35 illustrates an exemplary configuration of a resonator array structure according to Modification 20. The resonator array structure 300f of Modification 20 shown in FIG. 35 is obtained by filling a dielectric 321 into cells CSf corresponding to boundaries between slots SL(1) to SL(n) among a plurality of cells CS in the resonator array structure 300c of Modification 17. The cells CSf are filled with a dielectric 321, for example, from a base plate 320f up to an upper end of the resonator 301C. Since plasma is not generated in the cells CSf filled with the dielectric 321, plasma interference between the slots SL may be suppressed.

### (RF Power Feeding System)

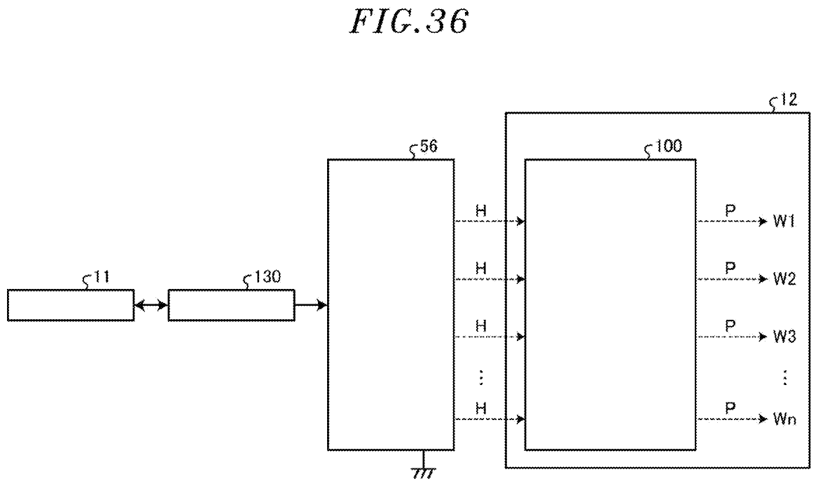

Next, an RF power feeding system according to first and second embodiments will be described with reference to FIGS. 36 to 41. FIG. 36 illustrates an exemplary configuration of an RF power feeding system according to the first and second embodiments. In FIG. 36, a plasma processing apparatus 1 of the first embodiment is described as an example. In the descriptions of FIGS. 36 to 41, processing gas and the like other than the RF power feeding system are omitted.

As shown in FIG. 36, in the RF power feeding system, a power setting Pset and a waveform setting of electromagnetic waves according to a recipe are input from a control device 11 to an RF power source 130. The waveform setting is waveform data for setting, for example, a center frequency and a waveform shape of the electromagnetic waves. The RF power source 130 generates electromagnetic waves according to the input power setting Pset and waveform setting and outputs the electromagnetic waves to an antenna 56. A magnetic field H is generated at the antenna 56 and is supplied to a resonator array structure 100 inside the processing container 12. Plasma P is generated in the resonator array structure 100, and substrates W1 to Wn are processed by the generated plasma. In the RF power feeding system of FIG. 36, one antenna 56 and a resonator array structure 100 having one resonance frequency are used, and the RF power source 130 outputs electromagnetic waves of a single-frequency single-peak waveform.

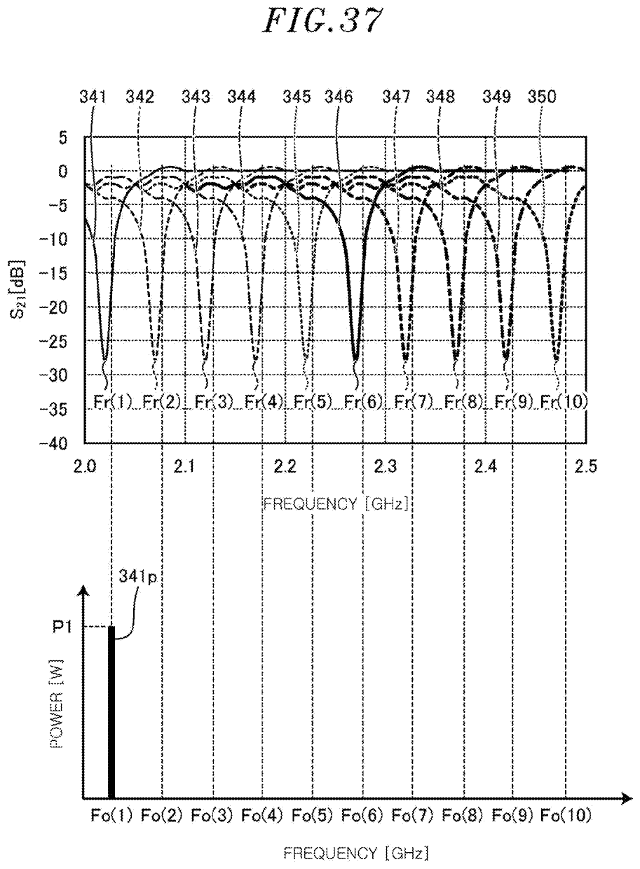

FIG. 37 illustrates exemplary settings for a resonance frequency of a resonator and an output of an RF power source according to the first and second embodiments. As shown in FIG. 37, a plurality of resonators 101 may be configured to have different resonance frequencies Fᵣ(1) to Fᵣ(10) expressed by graphs 341 to 350, for example, in a range of 2.0 GHz to 2.5 GHZ. In the RF power feeding system of FIG. 36, since the plurality of resonators 101 of the resonator array structure 100 are configured to have one resonance frequency Fᵣ(1), the control device 11 outputs, to the RF power source 130, a waveform setting having an output frequency Fₒ(1) and a power setting Pset=P1. When the waveform setting is input, the RF power source 130 generates electromagnetic waves having a power P1 as shown in graph 341p of FIG. 37 and outputs the electromagnetic waves to the antenna 56. A magnetic field H is generated at the antenna 56 and is supplied to the resonator array structure 100 inside the processing container 12. Since the plurality of resonators 101 of the resonator array structure 100 have the one resonance frequency Fᵣ(1), resonance occurs in all regions, and substrates W1 to Wn are processed by the generated plasma.

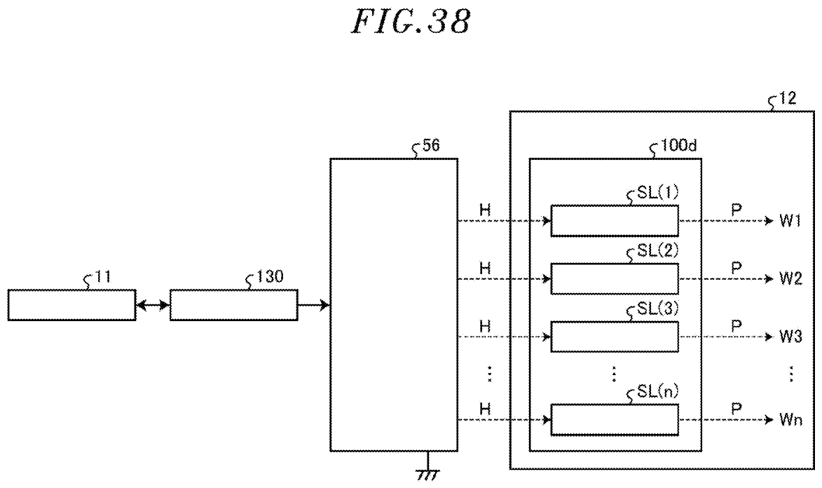

FIG. 38 illustrates an exemplary configuration of an RF power feeding system according to the first and second embodiments. FIG. 38 illustrates a case corresponding to Modifications 5 and 6 of the first embodiment and employing a resonator array structure 100d. In the RF power feeding system shown in FIG. 38, one antenna 56 and a resonator array structure 100d having resonance frequencies Fᵣ(1) to Fᵣ(n) are used, and the RF power source 130 outputs electromagnetic waves of a single-peak waveform with a variable single frequency. In the resonator array structure 100d, a plurality of resonators 101 at positions corresponding to slots SL(1) to SL(n) respectively have different resonance frequencies Fᵣ(1) to Fᵣ(n). The RF power source 130 sweeps output frequencies Fₒ(1) to Fₒ(n) using, for example, FM modulation and outputs electromagnetic waves of a single-peak waveform having output frequencies Fₒ(1) to Fₒ(n).

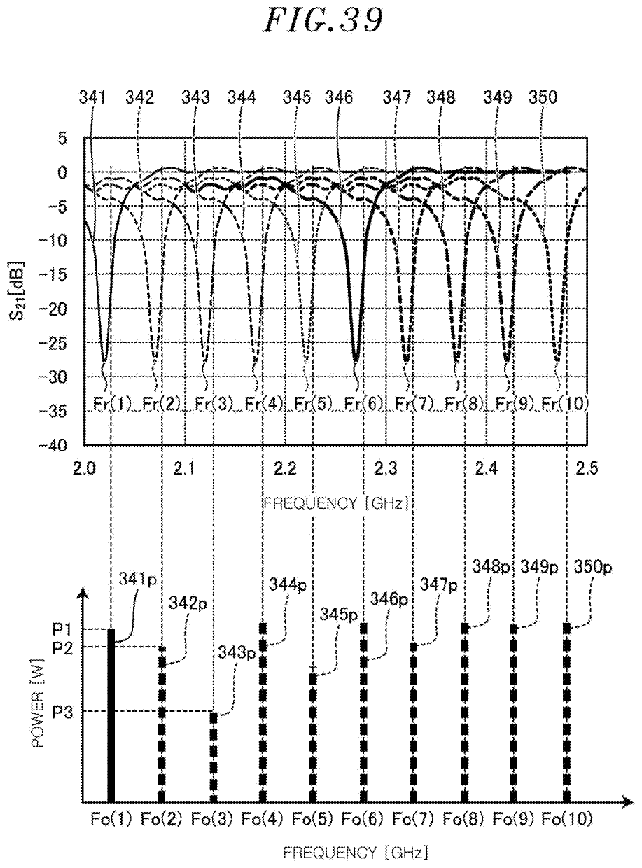

FIG. 39 illustrates exemplary settings for a resonance frequency of a resonator and an output of an RF power source according to the first and second embodiments. As shown in FIG. 39, the plurality of resonators 101 of the resonator array structure 100d are configured to have resonance frequencies Fᵣ(1) to Fᵣ(10). In the RF power feeding system of FIG. 38, the control device 11 outputs, to the RF power source 130, a waveform setting having output frequencies Fₒ(1) to Fₒ(10) and power settings Pset=P1 to P10. When the corresponding waveform setting is input, the RF power source 130 sweeps and generates electromagnetic waves having powers P1 to P10 as shown in graphs 341p to 350p of FIG. 39, and outputs the electromagnetic waves to the antenna 56. It should be noted that powers P4 to P10 (vertical axes) in graphs 344p to 350p are omitted from illustration. A magnetic field H is generated at the antenna 56 in accordance with the sweep and is supplied to the resonator array structure 100d inside the processing container 12. Since the plurality of resonators 101 of the resonator array structure 100d have resonance frequencies Fᵣ(1) to Fᵣ(10), resonance occurs at output frequencies Fₒ(1) to Fₒ(10) at which resonance is allowed. In other words, in the RF power feeding system of FIG. 38, plasma P generated in each of the slots SL(1) to SL(10) may be controlled by the output frequencies Fₒ(1) to Fₒ(10). In other words, in the RF power feeding system of FIG. 38, plasma processing may be performed by designating a specific substrate W among the plurality of substrates W.

FIG. 40 illustrates exemplary settings for a resonance frequency of a resonator and an output of an RF power source according to the first and second embodiments. FIG. 40 illustrates a case in which the RF power source 130 in the RF power feeding system shown in FIG. 38 outputs electromagnetic waves having a multi-tone broadband waveform. The control device 11 outputs waveform settings with a power setting Pset=P1 to P10 for output frequencies Fₒ(1) to Fₒ(10) to the RF power source 130. When the corresponding waveform settings are input, the RF power source 130 generates multi-tone electromagnetic waves of powers P1 to P10, as shown in graphs 341p to 350p of FIG. 40 and outputs them to the antenna 56. Note that the illustration of powers P4 to P10 (vertical axis) in graphs 344p to 350p is omitted. In the antenna 56, a magnetic field H is generated according to the multi-tones, and power is fed to the resonator array structure 100d within the processing container 12. Since the plurality of resonators 101 of the resonator array structure 100d have resonance frequencies Fᵣ(1) to Fᵣ(10), the plurality of resonators 101 resonate with respect to the resonance-capable output frequencies Fₒ(1) to Fₒ(10). In other words, in the RF power feeding system of FIG. 38, even when electromagnetic waves having a multi-tone broadband waveform are used, the plasma generated in each of the slots SL(1) to SL(10) may be controlled similarly to the case of a frequency sweep.

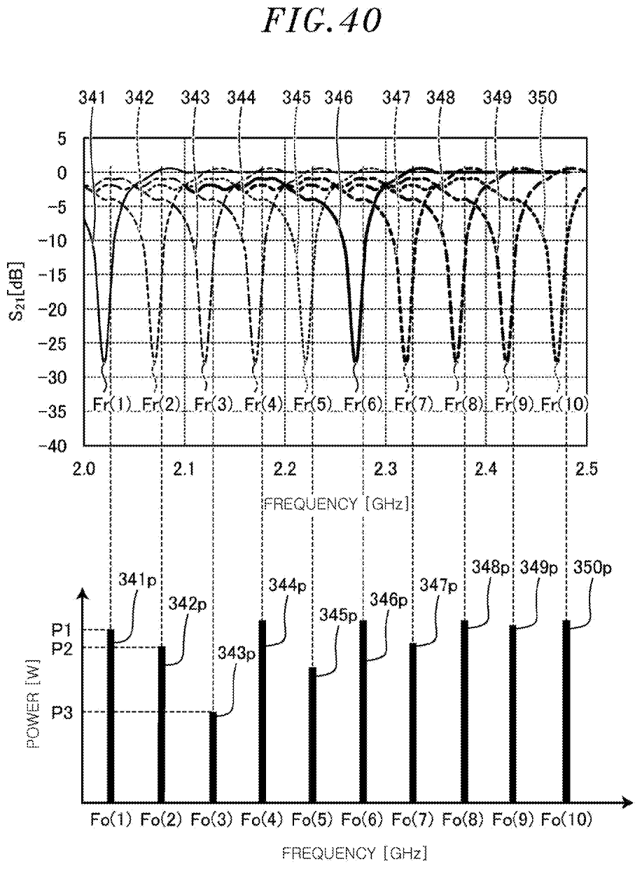

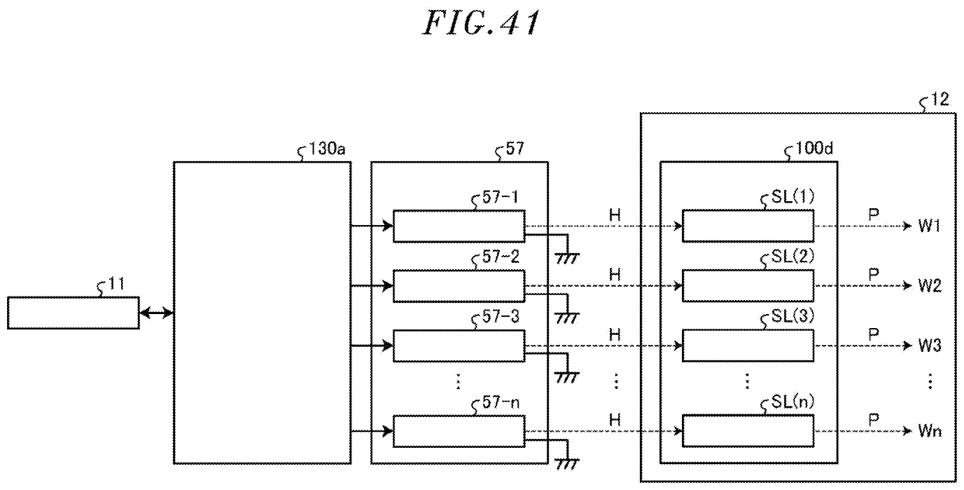

FIG. 41 illustrates exemplary configuration of an RF power feeding system according to the Modifications 5, 15 and 16. FIG. 41 corresponds to Modification 5 of the first embodiment and Modifications 15 and 16 of the second embodiment, and a case using the resonator array structure 100d is described as an example. In the RF power feeding system shown in FIG. 41, an antenna 57 (coils 57-1 to 57-n) and the resonator array structure 100d having resonance frequencies Fᵣ(1) to Fᵣ(n) are used, and an RF power source 130a outputs electromagnetic waves having a single-peak waveform of different frequencies for each of the coils 57-1 to 57-n. In the resonator array structure 100d, a plurality of resonators 101 at positions corresponding to the slots SL(1) to SL(n) have different resonance frequencies Fᵣ(1) to Fᵣ(n), respectively. The RF power source 130a outputs electromagnetic waves having a single-peak waveform with output frequencies Fₒ(1) to Fₒ(n) for each of the coils 57-1 to 57-n. Since the plurality of resonators 101 of the resonator array structure 100d have resonance frequencies Fᵣ(1) to Fᵣ(n), they resonate with respect to the resonance-capable output frequencies Fₒ(1) to Fₒ(n). In other words, in the RF power feeding system of FIG. 41, the plasma P generated in each of the slots SL(1) to SL(n) corresponding to the coils 57-1 to 57-n may be controlled by the output frequencies Fₒ(1) to Fₒ(n). In other words, in the RF power feeding system of FIG. 41, a specific substrate W among a plurality of substrates W may be designated and processed. Also, when performing distribution control within the surface of a single substrate W, the RF power source 130a may output electromagnetic waves having a multi-tone broadband waveform of different frequencies for each of the coils 57-1 to 57-n. Also, the RF power feeding systems shown in FIGS. 36 to 41 may be combined with the third and fourth embodiments and each modification described later as long as the combination does not raise an inconsistency issue.

### Third Embodiment

In the first embodiment described above, the resonator array structure 100 is disposed on the side surface of the processing container 12, but the resonator array structure may be disposed in each of the slots SL(1) to SL(n) of the wafer boat. An embodiment employing the above arrangement of the resonator array structure will be described as a third embodiment. Since the plasma processing apparatus in the third embodiment is the same as that of the first embodiment except for the configuration of the wafer boat, the configuration and arrangement of the antenna, and the arrangement and configuration of the resonator array structure, descriptions of overlapping configurations and operations will be omitted.

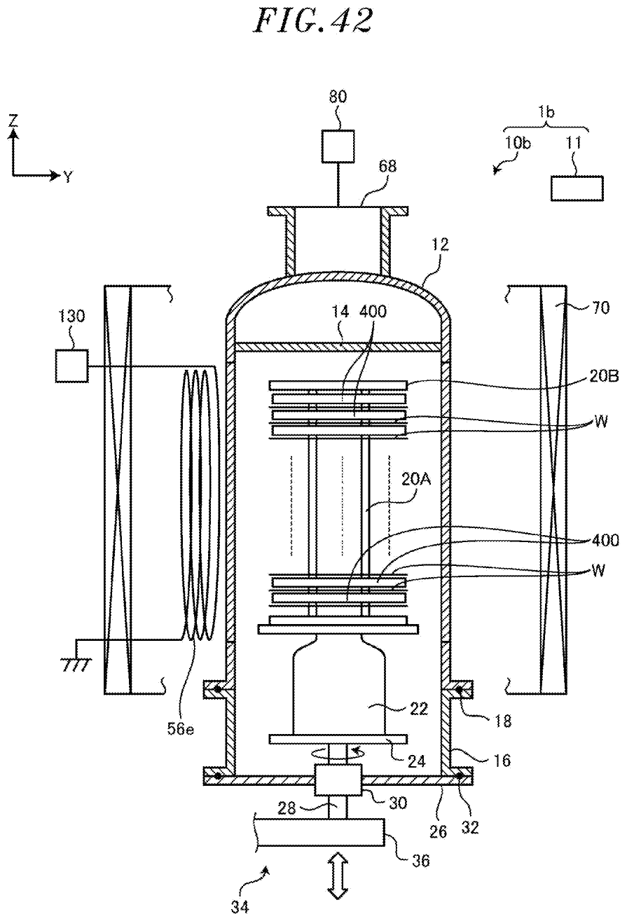

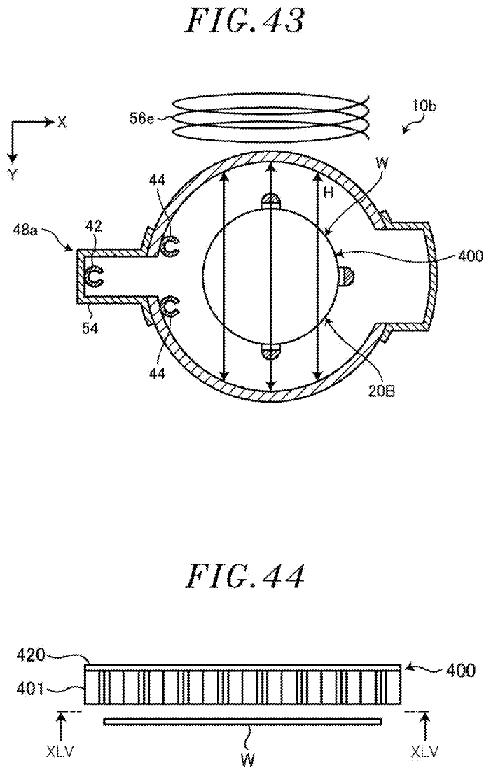

FIG. 42 is a schematic vertical cross-sectional view illustrating an exemplary configuration of a plasma processing apparatus according to the third embodiment. FIG. 43 is a schematic horizontal cross-sectional view illustrating an exemplary configuration of a plasma processing apparatus according to the third embodiment. While the apparatus main body 10 of the first embodiment shown in FIG. 1 has been described using a vertical cross-section in the X-axis direction, the apparatus main body 10b of the third embodiment shown in FIG. 42 will be described using a vertical cross-section in the Y-axis direction.

As shown in FIG. 42, the apparatus main body 10b of the plasma processing apparatus 1b of the third embodiment has a wafer boat 20B, an antenna 56e, and a resonator array structure 400 instead of the wafer boat 20, the antenna 56, and the resonator array structure 100 of the first embodiment.

In the wafer boat 20B, as shown in FIG. 42, a resonator array structure 400, a substrate W, a resonator array structure 400, a substrate W, . . . , a resonator array structure 400, and a substrate W are alternately held in order from the top. In other words, in the wafer boat 20B, a resonator array structure 400 is provided on a plane parallel to each substrate W for a plurality of substrates W.

The antenna 56e is disposed on a side surface of the processing container 12 (outside the processing container 12) so as to cover a width corresponding to the resonator array structures 400 held in the wafer boat 20B. Also, the antenna 56e is formed to be sufficiently long in a vertical direction so as to cover all of the resonator array structures 400 held in the wafer boat 20B along a longitudinal direction (vertical direction) in a height direction. The antenna 56e includes, for example, a solenoid-shaped coil. In other words, the antenna 56e is wound in a loop shape. The opening of the antenna 56e may be any shape such as a circle, an ellipse, or a polygon (e.g., a quadrilateral or a triangle). An RF power source 130 is connected to the antenna 56e, and a source RF signal is supplied to the antenna 56e. The magnetic field H generated by the antenna 56e is in the direction of the Y-axis shown in FIGS. 42 and 43. In the third embodiment, the plasma generator 48 of the first embodiment is used as a pipe 48a where a plasma gas distribution nozzle 42 is disposed.

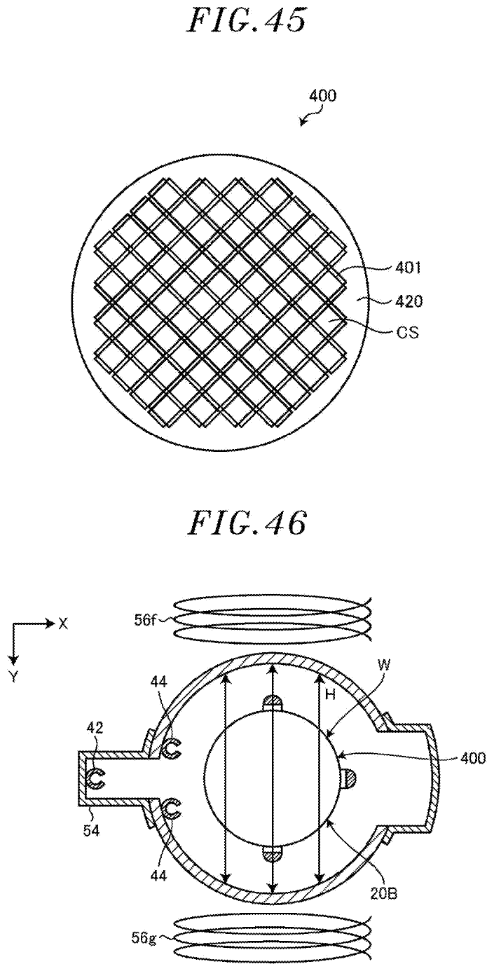

FIG. 44 is a side view illustrating an exemplary configuration of a resonator array structure according to the third embodiment. FIG. 45 is a plan view illustrating an exemplary configuration of the resonator array structure seen along the XLV-XLV cross-section of FIG. 44. As shown in FIG. 44, the resonator array structure 400 is arranged in the wafer boat 20B so that the base plate 420 faces upward and the plurality of resonators 401 face downward. The resonator array structure 400 is a cell-type resonator array structure similar to the resonator array structure 300 of the second embodiment. As shown in FIG. 45, in the resonator array structure 400, a plurality of resonators 401 are arranged perpendicularly to a circular base plate 420 having substantially the same diameter as the substrate W to form a plurality of cells CS. The base plate 420 may have a polygonal shape (a rectangular shape, a triangular shape, or the like). Furthermore, it is preferable that the range in which the cells CS exist in the resonator array structure 400 is larger than the diameter of the substrate W. The resonator array structure 400 is positioned above the substrate W so that the openings of the cells CS are located on the lower side. In the resonator array structure 400, as shown in FIGS. 42 and 43, since the magnetic field H passes through the side surface, i.e., through the plurality of resonators 401, plasma P is generated in each cell CS. The substrate W is processed by the plasma P generated in the cells CS. Since the configuration of the resonator 401 is the same as that of the resonator 301, the description thereof is omitted.

As described above, in the plasma processing apparatus 1b of the third embodiment, by employing non-contact power feeding to the resonator array structure 400 disposed for each substrate W in the wafer boat 20B, high-densification of plasma may be realized even in a so-called direct plasma-type plasma processing apparatus. Also, the direction in which the plasma P is generated may be selected by the opening direction of the cells CS of the resonator array structure 400. Furthermore, the distance between the resonator array structure 400 and the substrate W in the wafer boat 20B may be arbitrarily set.

### (Modification 21)

Next, Modification 21 will be described with reference to FIG. 46. Modification 21 is a modification of the antenna 56e. In Modification 21, antennas 56f and 56g are provided instead of the antenna 56e of the third embodiment. Therefore, in Modification 21, descriptions of overlapping configurations and operations of the same components as those of the first to third embodiments described above will be omitted.

FIG. 46 is a schematic horizontal cross-sectional view illustrating an exemplary configuration of a plasma processing apparatus according to Modification 21. Modification 21 shown in FIG. 46 includes antennas 56f and 56g instead of the antenna 56e of the third embodiment. Furthermore, the arrangement of the resonator array structure 400 of Modification 21 is the same as that of the third embodiment.

The antennas 56f and 56g are disposed being opposite each other on the side surfaces of the processing container 12 (outside the processing container 12) so as to cover a width corresponding to the resonator array structures 400 held in the wafer boat 20B, with the processing container 12 interposed therebetween. Since each of the antennas 56f and 56g generates a magnetic field H, the magnetic field H penetrates from both sides of the resonator array structure 400 in the Y-axis direction. In contrast, in the antenna 56e of the third embodiment, since the magnetic field H penetrates from one side of the resonator array structure 400 in the Y-axis direction, the magnetic field H is absorbed by the resonators 401 of the cells CS closer to the antenna 56e, and the magnetic field H reaching the resonators 401 of distant cells CS is attenuated. In other words, plasma density varies in each cell CS of the resonator array structure 400. In Modification 21, since the magnetic field H penetrates from both sides of the resonator array structure 400, the deviation of the magnetic field H in the Y-axis direction is reduced, thereby improving plasma uniformity.

### (Modifications 22 and 23)

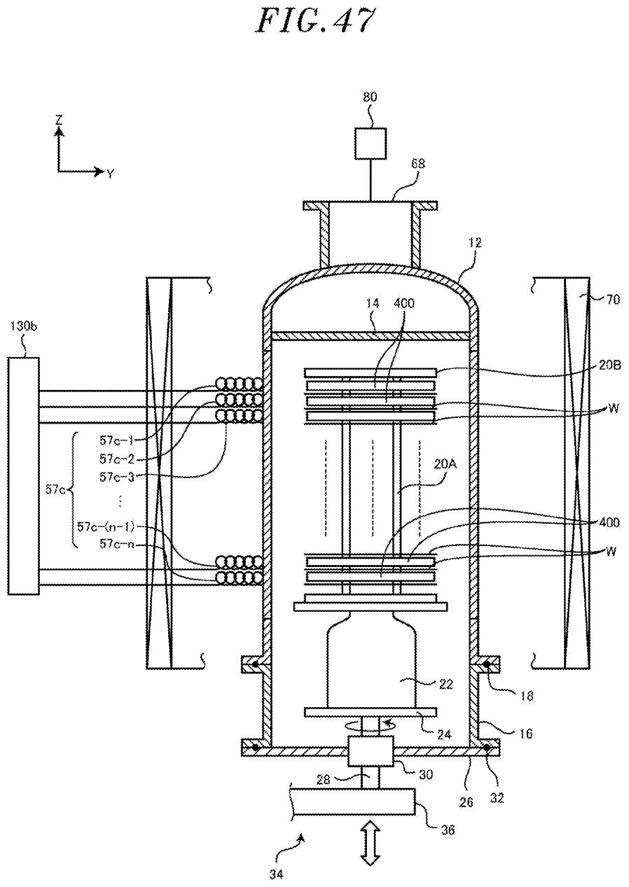

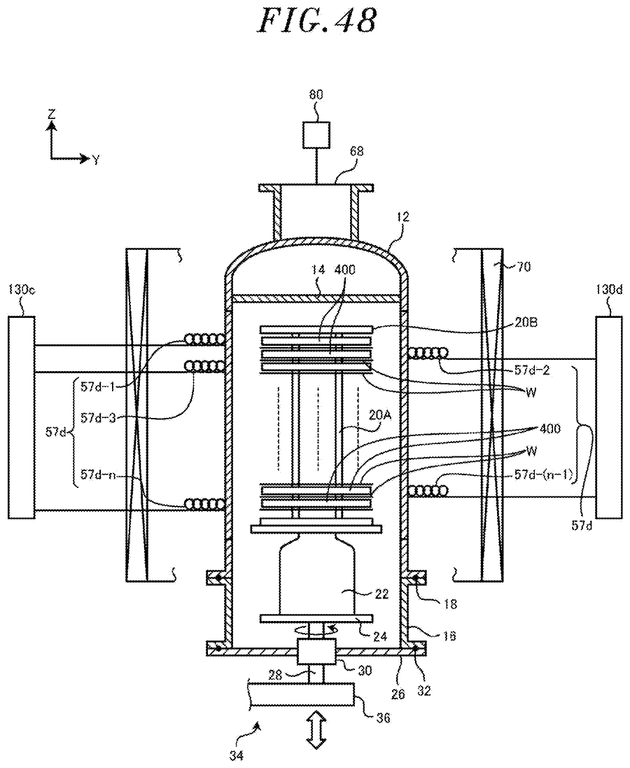

Next, Modifications 22 and 23 of the third embodiment will be described with reference to FIGS. 47 and 48. Modifications 22 and 23 are modifications of the antenna 56e. In Modification 22, an antenna 57c and an RF power source 130b are provided instead of the antenna 56e and the RF power source 130 of the third embodiment. Therefore, in Modification 22, descriptions of configurations and operations that overlap with those of the first to third embodiments described above will be omitted. Furthermore, Modification 22 corresponds to Modification 5 of the first embodiment and Modification 15 of the second embodiment.

FIG. 47 is a schematic vertical cross-sectional view illustrating an exemplary configuration of a plasma processing apparatus according to Modification 22. Modification 22 shown in FIG. 47 has an antenna 57c and an RF power source 130b instead of the antenna 56e and the RF power source 130 of the third embodiment.

Similarly to the case of antenna 56e, the antenna 57c is disposed on the side surface of the processing container 12 (outside the processing container 12) so as to cover a width corresponding to the resonator array structures 400 held in the wafer boat 20B. The antenna 57c includes a plurality of coils 57c-1 to 57c-n. Each of the coils 57c-1 to 57c-n is, for example, wound in a loop shape. The openings of the coils 57c-1 to 57c-n may have any shape such as a circle, an ellipse, or a polygon (e.g., a quadrilateral or a triangle). The openings of the coils 57c-1 to 57c-n face the side surface (Y-axis direction) of the resonator array structure 400 held in the wafer boat 20B. The RF power source 130b is connected to the coils 57c-1 to 57c-n, and source RF signals are supplied to the coils 57c-1 to 57c-n. Each magnetic field H generated by the coils 57c-1 to 57c-n is in the Y-axis direction shown in FIG. 47.

The coils 57c-1 to 57c-n correspond to, for example, each of the resonator array structures 400 held in the wafer boat 20B and supply a magnetic field H (electromagnetic wave) to each resonator array structure 400. In Modification 22, each resonator array structure 400 has a different resonance frequency.

Similarly to Modification 15 of the second embodiment, the RF power source 130b is coupled to the coils 57c-1 to 57c-n of the antenna 57c, and each coil is configured to generate a source RF signal (source RF power) for plasma generation through at least one impedance matching circuit. The RF power source 130b may individually supply source RF signals to each of the coils 57c-1 to 57c-n. The RF power source 130b generates source RF signals of different frequencies for each of the coils 57c-1 to 57c-n. In this case, since the resonance frequency of each resonator 401 in the resonator array structure 400 is different, the resonator resonates by the magnetic field H of the corresponding coil 57c-1 to 57c-n. As described above, by changing the source RF signal supplied to each of the coils 57c-1 to 57c-n, the plasma density (processing rate) among the plurality of substrates W may be arbitrarily controlled.

FIG. 48 is a schematic vertical cross-sectional view illustrating an exemplary configuration of a plasma processing apparatus according to Modification 23. In Modification 23, an antenna 57d and RF power sources 130c and 130d are provided instead of the antenna 56e and the RF power source 130 of the third embodiment. Therefore, in Modification 23, descriptions of overlapping configurations and operations of the same components as those of the first to third embodiments described above will be omitted.

Modification 23 shown in FIG. 48 has an antenna 57d and RF power sources 130c and 130d instead of the antenna 56e and the RF power source 130 of the third embodiment. In Modification 23, the coils 57c-1 to 57c-n of the antenna 57c of Modification 22 are alternately arranged in a staggered manner with the processing container 12 interposed therebetween, similarly to cases of antennas 56f and 56g of Modification 21.

Similarly to cases of the antennas 56f and 56g, each coil of the antenna 57d is disposed on the side surfaces of the processing container 12 (outside the processing container 12) so as to face each other with the processing container 12 interposed therebetween and to cover a width corresponding to the resonator array structures 400 held in the wafer boat 20B. The antenna 57d has a plurality of coils 57d-1 to 57d-n. Each of the coils 57d-1 to 57d-n is wound in a loop shape. The openings of the coils 57d-1 to 57d-n may have any shape such as a circle, an ellipse, or a polygon (e.g., a quadrilateral or a triangle). The openings of the coils 57d-1 to 57d-n face the side surface (Y-axis direction) of the resonator array structure 400 held in the wafer boat 20B. For example, coils 57d-1, 57d-3, . . . , 57d-n are disposed on the left side of the processing container 12 in FIG. 48, and coils 57d-2, 57d-4, . . . , 57d-(n−1) are disposed on the right side of the processing container 12. The RF power source 130c is connected to the coils 57d-1, 57d-3, . . . , 57d-n, and source RF signals are supplied to the coils 57d-1, 57d-3, . . . , 57d-n. The RF power source 130d is connected to the coils 57d-2, 57d-4, . . . , 57d-(n−1), and source RF signals are supplied to the coils 57d-2, 57d-4, . . . , 57d-(n−1). The RF power sources 130c and 130d are obtained by dividing the RF power source 130b according to the arrangement of the coils 57d-1 to 57d-n. Also, the RF power sources 130c and 130d may be replaced with one RF power source 130b. Each magnetic field H generated by the coils 57d-1 to 57d-n is in the Y-axis direction shown in FIG. 48.

### (Modifications 24 to 27)

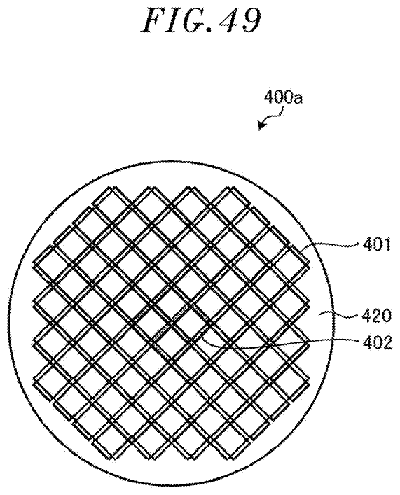

Next, Modifications 24 to 27 of the third embodiment will be described with reference to FIGS. 49 to 53. Modifications 24 to 27 are modifications of the resonator array structure 400. In Modifications 24 to 26, resonator array structures 400a to 400c are provided respectively instead of the resonator array structure 400 of the third embodiment. Also, Modification 27 illustrates a resonator 401A applicable to the resonator array structure 400a to 400c instead of the resonator 401. Therefore, in Modifications 24 to 27, descriptions of configurations that overlap with those of the third embodiment described above will be omitted.

FIG. 49 is a plan view illustrating an exemplary configuration of a resonator array structure according to Modification 24. In the resonator array structure 400a of Modification 24 shown in FIG. 49, for example, a plurality of resonators 402 are disposed in four cells CS at the center of the base plate 420, while a plurality of resonators 401 are disposed in the other portions of the base plate 420 to form cells CS. Resonators 402 have a different resonance frequency from those of resonators 401. In other words, the resonator array structure 400a may, for example, perform density control of plasma (control of processing rate) at a central portion and a peripheral portion of the substrate W by an RF power source 130a that outputs electromagnetic waves of two output frequencies Fₒ(1) and Fₒ(2) in a swept manner or as a broadband waveform.

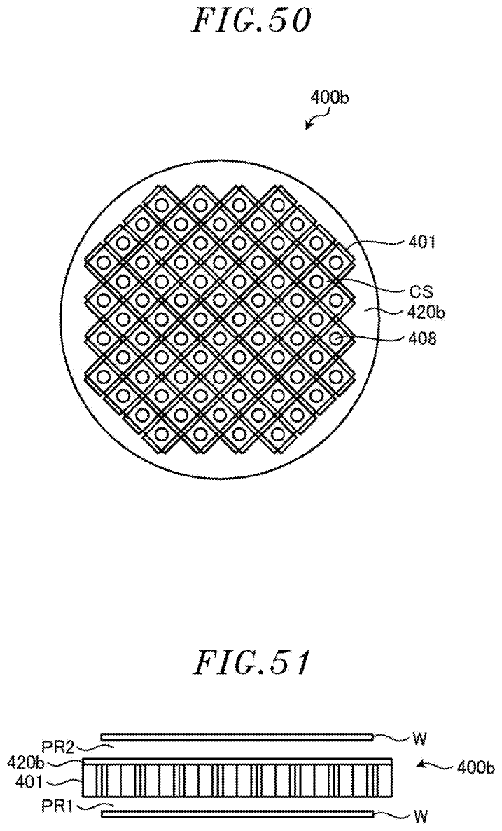

FIG. 50 is a plan view illustrating an exemplary configuration of a resonator array structure according to Modification 25. FIG. 51 illustrates a relationship between a resonator array structure and a substrate according to the Modification 25. In the resonator array structure 400b of Modification 25 shown in FIG. 50, a through-hole 408 is provided in each of a plurality of cells CS arranged in a lattice shape. The through-hole 408 is provided at the center of the cell CS and is formed to penetrate the base plate 420b. Here, as shown in FIG. 51, the resonator array structure 400b is viewed from a side surface while being held by a wafer boat 20B. Since the resonator array structure 400b includes the through holes 408 formed in the base plate 420b, plasma processing may be performed on both sides of a plasma generation surface PR1 on a resonator 401 side (lower side) and a plasma generation surface PR2 on a base plate 420b side (upper side). Also, the plasma density on the plasma generation surface PR1 side is higher than that on the plasma generation surface PR2 side.

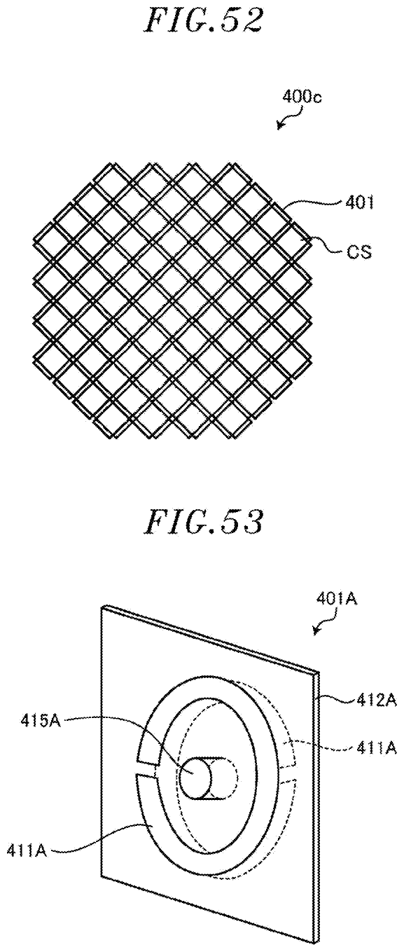

FIG. 52 is a plan view illustrating an exemplary configuration of a resonator array structure according to Modification 26. The resonator array structure 400c of Modification 26 shown in FIG. 52 is obtained by omitting the base plate 420b from the resonator array structure 400b of Modification 25. In the resonator array structure 400c, each resonator 401 is connected, for example, by welding. Since the resonator array structure 400c does not include the base plate 420b, plasma densities on an upper side and a lower side of the resonator array structure 400c are equal. For example, if a substrate W arranged on an upper side is held by the wafer boat 20B in an inverted orientation upside down, two substrates W, one on the upper side and one on the lower side of the wafer boat 20B, may be plasma-processed using a single resonator array structure 400c.

FIG. 53 is a view illustrating an exemplary configuration of a resonator according to Modification 27. The resonator 401A shown in FIG. 53 has a structure in which a dielectric plate 412A is disposed between two C-shaped ring members 411A made of a conductor and arranged adjacent to each other in opposite directions. In other words, in the resonator 401A, the dielectric plate 412A is interposed between the two C-shaped ring members 411A oriented in opposite directions. Capacitor equivalent elements are formed at opposing surfaces of the two C-shaped ring members 411A or at both ends of each ring member 411A, and inductor-equivalent elements are formed along each ring member 411A. Accordingly, the resonator 401A may constitute a series resonance circuit. Also, the resonator 401A includes a through hole 415A at the center thereof. By providing the through hole 415A, gas or plasma may flow into and out of a cell CS formed by the resonator 401A between adjacent cells CS. The resonator 401A may also be described as being formed for each pair of two C-shaped ring members 411A.

### Fourth Embodiment

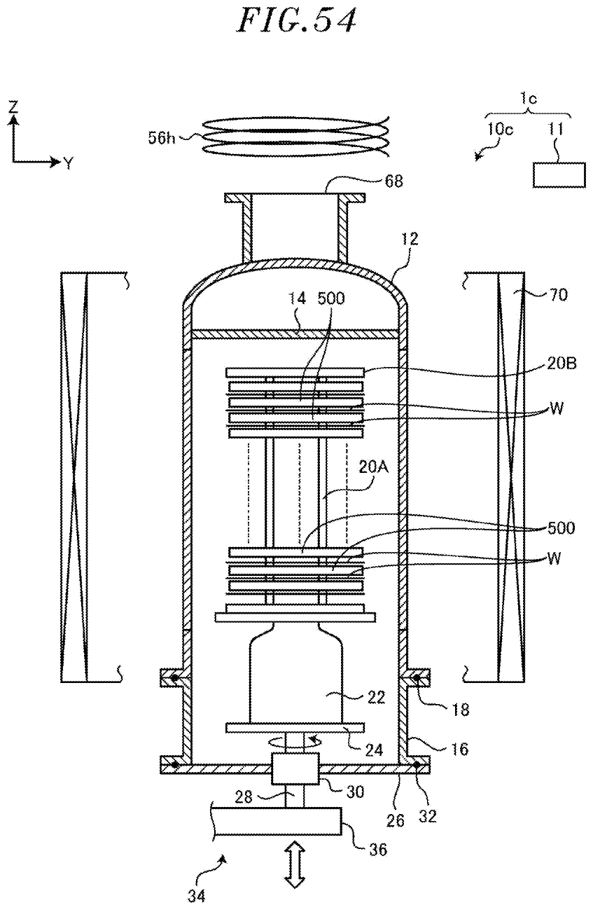

FIG. 54 is a schematic vertical cross-sectional view illustrating an exemplary configuration of a plasma processing apparatus according to a fourth embodiment. As shown in FIG. 54, an apparatus main body 10c of a plasma processing apparatus 1c of the fourth embodiment includes an antenna 56h and a resonator array structure 500 instead of the antenna 56e and the resonator array structure 400 of the third embodiment.

The antenna 56h is arranged above an upper portion of the processing container 12, for example, above a gas outlet 68 (outside the processing container 12), so as to cover a width corresponding to a diameter of the resonator array structure 500 held by the wafer boat 20B. The antenna 56h includes, for example, a solenoid-shaped coil. In other words, the antenna 56h is wound in a loop shape. The opening of the antenna 56h may have any shape such as a circle, an ellipse, or a polygon (e.g., a quadrilateral or a triangle). An RF power source 130 is connected (actual connection is not shown) to the antenna 56h, and a source RF signal is supplied to the antenna 56h. A magnetic field H generated by the antenna 56h extends in the Z-axis direction shown in FIG. 54.

### (Modification 28)

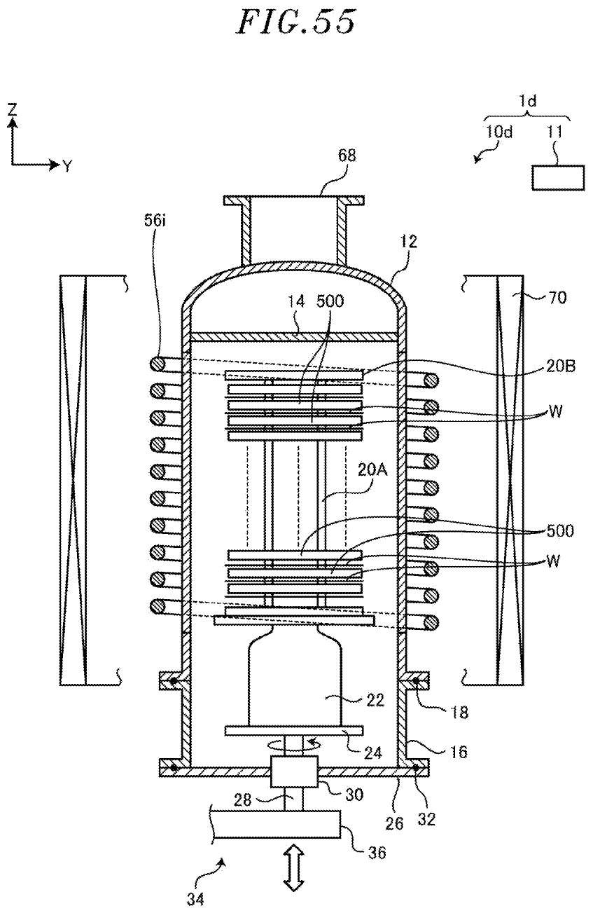

FIG. 55 is a schematic vertical cross-sectional view illustrating an exemplary configuration of a plasma processing apparatus according to Modification 28. As shown in FIG. 55, an apparatus main body 10d of a plasma processing apparatus 1d of Modification 28 includes an antenna 56i and a resonator array structure 500 instead of the antenna 56e and the resonator array structure 400 of the third embodiment.

The antenna 56i is disposed outside the processing container 12 so as to surround a side surface of the processing container 12. In other words, the processing container 12 is disposed within a solenoid-shaped coil of the antenna 56i. The antenna 56i is wound in a loop shape. Also, the antenna 56i is formed to be sufficiently long in a vertical direction so as to cover all of the resonator array structures 500 held by the wafer boat 20B in a height direction. The opening of the antenna 56i may have any shape such as a circle, an ellipse, or a polygon (e.g., a quadrilateral or a triangle). An RF power source 130 is connected (actual connection is not shown) to the antenna 56i, and a source RF signal is supplied to the antenna 56i. A magnetic field H generated by the antenna 56i extends in the Z-axis direction shown in FIG. 55.

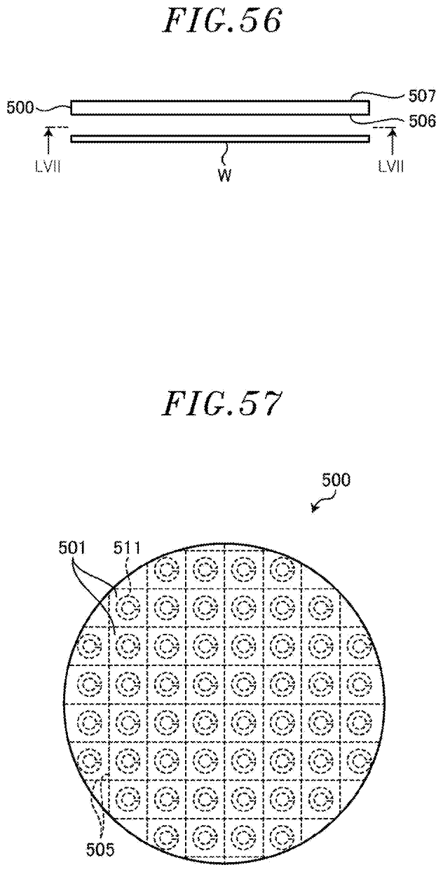

FIG. 56 is a side view illustrating an exemplary configuration of a resonator array structure according to the fourth embodiment and the Modification 28. FIG. 57 is a plan view illustrating an exemplary configuration of the resonator array structure seen along the LVII-LVII cross-section of FIG. 56. As shown in FIG. 56, the resonator array structure 500 has the same planar configuration as the resonator array structure 100 of the first embodiment. As shown in FIG. 57, a plurality of resonators 501 are disposed on the same plane in the planar resonator array structure 500. In other words, the plurality of resonators 501 are arranged on a plane parallel to a plane extending in a longitudinal direction of the resonator array structure 500. In other words, when viewed from a substrate W side located below in the wafer boat 20B, C-shaped ring members 511 that appear through the structure are arranged in a lattice pattern so that C shapes are visible. Also, the resonator array structure 500 has a circular shape having substantially the same diameter as the substrate W. Also, the resonator array structure 500 may have a polygonal shape (e.g., a quadrilateral or a triangle). It is preferable for the resonator array structure 500 that a region in which the resonators 501 are present is larger than the diameter of the substrate W. As shown in FIGS. 54 and 55, since the magnetic field H passes through the plurality of resonators 501 of the planar resonator array structure 500, plasma is generated on the plane. The substrate W is processed by the generated plasma. Since the configuration of the resonators 501 is the same as that of the resonators 101, descriptions thereof will be omitted.

The first surface 506 of the resonator array structure 500 is a surface facing, in the wafer boat 20B, a lower substrate W to be processed, and the second surface 507 is a surface facing, in the wafer boat 20B, an upper substrate W that is not to be processed. In other words, the resonator array structure 500 is disposed such that the first surface 506 faces downward and the second surface 507 faces upward. Similar to the resonator array structure 100, the resonator array structure 500 is formed such that a dielectric thickness from a first C-shaped ring member 511 to the first surface 506 is thinner than a dielectric thickness from a second C-shaped ring member 511 to the second surface 507. Accordingly, in the resonator array structure 500, plasma may be selectively generated on the first surface 506 side, which faces the lower substrate W to be processed in the wafer boat 20B. In other words, the resonator array structure 500 may control a plasma generation surface based on a dielectric thickness from each ring member 511 of the resonators 501 to the surface.

In the fourth embodiment, among the resonator array structures 500 held in the wafer boat 20B, each resonator 501 may sequentially resonate at a corresponding frequency from the top, thereby absorbing a magnetic field H to generate plasma, and the remaining magnetic field H (at a different frequency) may resonate with the next resonator array structure 500. In other words, the RF power source 130 of the fourth embodiment supplies electromagnetic waves to the plurality of resonator array structures 500 held in the wafer boat 20B to cause each resonator 501 to resonate. Accordingly, in the fourth embodiment, plasma is generated in each resonator array structure 500 held in the wafer boat 20B, and a plurality of substrates W are processed.

In Modification 28, a magnetic field H passing through a solenoid-shaped coil of an antenna 56i is supplied to each resonator array structure 500 held in the wafer boat 20B. Each resonator 501 of each resonator array structure 500 resonates to absorb the magnetic field H, thereby generating plasma. In other words, the RF power source 130 of Modification 28 supplies electromagnetic waves to the plurality of resonator array structures 500 held in the wafer boat 20B to cause each resonator 501 to resonate. Accordingly, in Modification 28, plasma is generated in each resonator array structure 500 held in the wafer boat 20B, and a plurality of substrates W are processed.

### (Modifications 29 and 30)

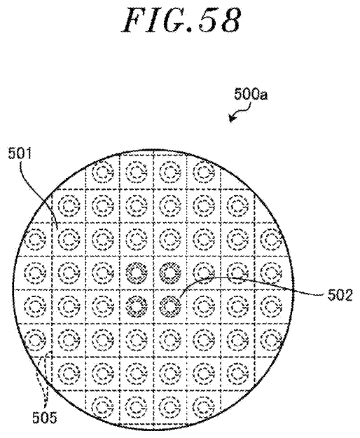

Next, Modifications 29 and 30 of the fourth embodiment will be described with reference to FIGS. 58 to 60. Modifications 29 and 30 are modification examples of the resonator array structure 500. In Modifications 29 and 30, resonator array structures 500a and 500b are provided instead of the resonator array structure 500 of the fourth embodiment, respectively. In Modifications 29 and 30, descriptions of configurations and operations that overlap with those of the first to fourth embodiments are omitted.

FIG. 58 is a plan view illustrating an exemplary configuration of a resonator array structure according to Modification 29. In the resonator array structure 500a of Modification 29 shown in FIG. 58, for example, four resonators 502 are disposed in a central portion of the resonator array structure 500a, and a plurality of resonators 501 are disposed in other portions. The resonators 502 have resonance frequencies different from those of the resonators 501. In other words, the resonator array structure 500a may, for example, perform density control of plasma (control of processing rate) at a central portion and a peripheral portion of the substrate W using an RF power source 130a that outputs electromagnetic waves of two output frequencies Fₒ(1) and Fₒ(2) in a swept manner or as a broadband waveform.

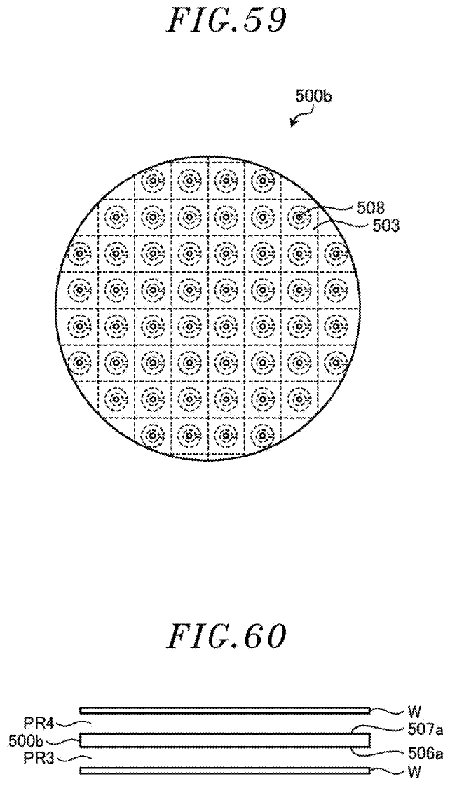

FIG. 59 is a plan view illustrating an exemplary configuration of a resonator array structure according to Modification 30. FIG. 60 illustrates a relationship between a resonator array structure and a substrate according to Modification 30. In the resonator array structure 500b of Modification 30 shown in FIG. 59, each of a plurality of resonators 503 arranged in a lattice pattern is provided with a through hole 508. The through hole 508 is provided at a center of the resonator 503 and is formed to penetrate a dielectric at a center between two C-shaped ring members 511. In other words, the through hole 508 penetrates the first surface 506a and the second surface 507a of the resonator array structure 500b. Here, as shown in FIG. 60, the resonator array structure 500b is viewed from a side surface while being held in the wafer boat 20B. Since the resonator array structure 500b includes the through holes 508, plasma processing may be performed on both sides of a plasma generation surface PR3 on the first surface 506a side (lower side) and a plasma generation surface PR4 on the second surface 507a side (upper side). When plasma is generated on both sides of the resonator array structure 500b, the dielectric thickness from each ring member 511 to the surface is made uniform. In this case, the plasma density becomes equivalent at the plasma generation surfaces PR3 and PR4.

### (RF Power Feeding System of the Fourth Embodiment)

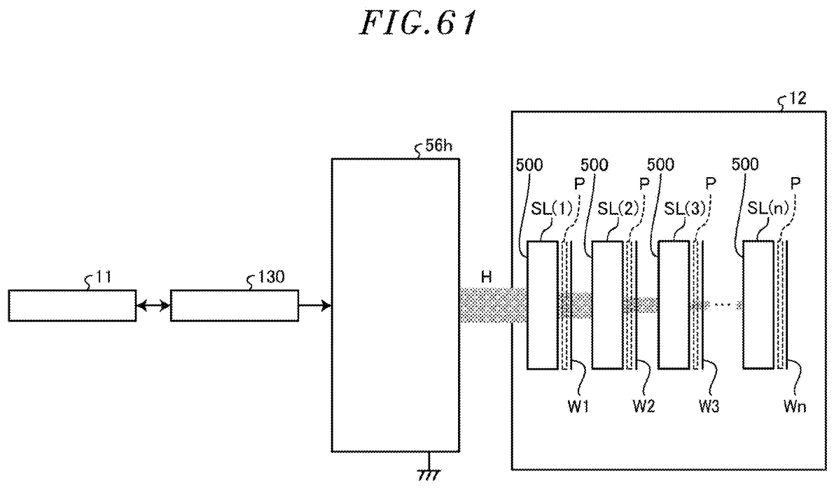

Next, an RF power feeding system according to the fourth embodiment will be described with reference to FIG. 61. FIG. 61 illustrates an exemplary configuration of an RF power feeding system according to the fourth embodiment. In the description of FIG. 61, processing gas and the like other than the RF power feeding system are omitted.

In the RF power feeding system shown in FIG. 61, one antenna 56h and resonator array structures 500 having resonance frequencies Fᵣ(1) to Fᵣ(n) are used, and the RF power source 130 outputs electromagnetic waves of a single-peak waveform with a variable single frequency. Each resonator array structure 500 corresponding to each of slots SL(1) to SL(n) includes a plurality of resonators 501 having different resonance frequencies Fᵣ(1) to Fᵣ(n). The RF power source 130 sweeps output frequencies Fₒ(1) to Fₒ(n) using, for example, FM modulation, and outputs electromagnetic waves of a single-peak waveform having the output frequencies Fₒ(1) to Fₒ(n). In the RF power feeding system shown in FIG. 61, in the resonator array structures 500 held in the wafer boat 20B, each resonator 501 may sequentially resonate at a corresponding frequency from the top, thereby absorbing the magnetic field H to generate plasma P, and the remaining magnetic field H of a different frequency may resonate with the next resonator array structure 500. At this time, the plasma P generated in each resonator array structure 500 has a positive or negative refractive index, thereby allowing electromagnetic waves to penetrate. Also, in the RF power feeding system shown in FIG. 61, the RF power source 130 may output electromagnetic waves of a multi-tone broadband waveform. Further, the same RF power feeding system as that of FIG. 61 may be used for a case of using the antenna 56i of Modification 28. As described above, in the RF power feeding system shown in FIG. 61, although batch feeding is performed from a serial direction with respect to the resonator array structures 500, plasma generated in each of slots SL(1) to SL(n) may be controlled.

As described above, according to each embodiment, a plasma processing apparatus 1 and 1a to 1d includes a processing container 12 and 12a at least partially formed of a first dielectric, a substrate holding part (wafer boat 20 and 20B) configured to hold a plurality of substrates W in the processing container, an electromagnetic wave generator (RF power source 130 and 130a to 130d) configured to generate electromagnetic waves for plasma excitation supplied into the processing container, an electromagnetic wave supply part (antennas 56, 56a to 56i, 57, and 57a to 57d) configured to supply the electromagnetic waves into the processing container through the first dielectric, and a resonator array structure 100, 100a to 100f, 300, 300a to 300f, 400, 400a to 400c, 500, 500a, and 500b located in a region within the processing container where the electromagnetic waves may be supplied through the first dielectric. The resonator array structure is configured to include a plurality of resonators 101, 101A, 101B, 301, 301B, 301C, 401, 402, and 501 to 503 capable of resonating with a magnetic field component of the electromagnetic waves, have sizes smaller than a wavelength of the electromagnetic waves, and are disposed on the same plane. The electromagnetic wave supply part supplies a magnetic field component perpendicular to the plane in which the plurality of resonators are arranged. As a result, high-densification of plasma may be achieved even in a so-called batch-type plasma processing apparatus.

Also, according to the first and second embodiments, the resonator array structures 100 and 300 are provided within a plasma generation chamber (plasma generator 48) partitioned by a plasma partition wall 54 provided along a longitudinal direction of the processing container. As a result, high-densification of plasma may be achieved even in so-called remote plasma.

Also, according to the first and second embodiments, the processing container may include a side wall composed of a first dielectric, and a resonator array structure 100a to 100c, 300a, and 300b may be provided between the side wall of the processing container and a substrate holding part (wafer boat 20). As a result, higher densification of plasma may be achieved.

Also, according to the first and fourth embodiments, a plurality of resonators 101 and 501 may be disposed on a plane parallel to a longitudinal surface of the resonator array structure 100, 100a to 100c, 500, 500a, and 500b. As a result, the structure of the resonator array structure may be simplified.

Also, according to the first and second embodiments, the plurality of resonators 101 and 301B may have a structure in which C-shaped ring members 111 and 311B made of a conductor are stacked on both surfaces of a dielectric plate 112 and 312B. Further, the C-shaped ring members may be covered with a second dielectric, and the second dielectric (with a dielectric 112 thickness 109a and 109b and film 313) may have a thickness of a substrate holding part side that is smaller than a thickness of an electromagnetic wave supply side. As a result, plasma may be selectively generated on the substrate holding part side.

Also, according to the second and third embodiments, the plurality of resonators 301, 301B, 301C, 401, and 402 may be disposed on a plane perpendicular to a longitudinal surface of the resonator array structure 300, 300a to 300f, 400, and 400a to 400c. As a result, cells CS may be formed, and high-densification of plasma may be achieved.

Also, according to the second and third embodiments, in the resonator array structure, a plurality of cells CS surrounded by the plurality of resonators may be formed, and the cells CS may be disposed in a lattice pattern. As a result, plasma may be generated inside the cells CS.

Also, according to each embodiment, an electromagnetic wave supply part may be a coil provided outside the processing container. As a result, electromagnetic waves may be supplied to each resonator of the resonator array structure by non-contact power feeding from outside the processing container.

Also, according to each embodiment, the coil may be disposed such that an opening of the coil is parallel to the plurality of resonators. As a result, electromagnetic waves may be supplied to each resonator of the resonator array structure by non-contact power feeding from outside the processing container.

Also, according to the first embodiment, the plurality of resonators may be arranged in a lattice pattern on a plane parallel to a longitudinal surface of the resonator array structure. Also, a plurality of coils 57-1 to 57-n may be provided at positions corresponding to the plurality of resonators arranged in regions of the resonator array structure corresponding to the respective substrates W of the substrate holding part. As a result, plasma density (processing rate) between the plurality of substrates W may be arbitrarily controlled.

Also, according to the second embodiment, the plurality of resonators may be disposed on a plane perpendicular to a longitudinal surface of the resonator array structure, a plurality of cells CS surrounded by the plurality of resonators may be formed, and the cells CS may be arranged in a lattice pattern. Also, a plurality of coils 57a-1 to 57a-n may be provided at positions corresponding to the cells CS arranged in regions of the resonator array structure corresponding to the respective substrates W of the substrate holding part. As a result, plasma density (processing rate) between the plurality of substrates W may be arbitrarily controlled.

Also, according to the second embodiment, the coils 57b-1 to 57b-n may be arranged in a staggered manner for each region of the resonator array structure. As a result, plasma density (processing rate) between the plurality of substrates W may be arbitrarily controlled.

Also, according to the second embodiment, the plurality of resonators may have different resonance frequencies for each region. As a result, plasma density (processing rate) between the plurality of substrates W may be arbitrarily controlled.

Also, according to the third and fourth embodiments, the resonator array structure 400, 400a to 400c, 500, 500a, and 500b may be provided on a plane parallel to the substrate W. As a result, even in a so-called direct plasma type plasma processing apparatus, high-densification of plasma may be achieved.

Also, according to the third and fourth embodiments, the resonator array structure may be provided for each of the plurality of substrates W. As a result, high-densification of plasma may be achieved.

Also, according to the third embodiment, the plurality of resonators may be disposed on a plane perpendicular to a longitudinal surface of the resonator array structure. As a result, cells CS may be formed, and high-densification of plasma may be achieved.

Also, according to the third embodiment, in the resonator array structure, a plurality of cells CS surrounded by the plurality of resonators may be formed, and the cells CS may be arranged in a lattice pattern. As a result, plasma may be generated inside the cells CS.

Also, according to the fourth embodiment, the plurality of resonators may be arranged in a lattice pattern on a plane parallel to a longitudinal surface of the resonator array structure. As a result, the structure of the resonator array structure may be simplified.

Also, according to the fourth embodiment, the plurality of resonators may have a structure in which C-shaped ring members 511 made of a conductor are stacked on both surfaces of a dielectric plate. Further, the C-shaped ring members 511 may be covered with a second dielectric, and the second dielectric may have a thickness of a processing target surface side (the first surface 506) of the substrate W that is smaller than a thickness of an opposite surface (the second surface 507) side. As a result, plasma may be selectively generated on the processing target surface side of the substrate W.

Also, according to the third embodiment, the electromagnetic wave supply part may be a coil 57c-1 to 57c-n and 57d-1 to 57d-n provided outside the processing container. Further, the coil may be provided for each resonator array structure corresponding to each substrate W of the substrate holding part. As a result, plasma density (processing rate) between the plurality of substrates W may be arbitrarily controlled.

Also, according to the fourth embodiment, the electromagnetic wave supply part may be a coil 56h and 56i provided outside the processing container. Further, the coil may be disposed such that an opening of the coil is parallel to the plurality of resonators 501 to 503 and may supply a magnetic field component in a direction in which a magnetic field penetrates the plurality of resonator array structures 500, 500a, and 500b. As a result, even when planar resonator array structures are disposed for each substrate W, plasma may be generated in each resonator array structure, and plasma density (processing rate) between the plurality of substrates W may be arbitrarily controlled.

Also, according to the third and fourth embodiments, the plurality of resonators may have different resonance frequencies for each resonator array structure. As a result, plasma density (processing rate) between the plurality of substrates W may be arbitrarily controlled.

Also, according to the third and fourth embodiments, the resonator array structure may have different resonance frequencies among a plurality of resonators corresponding to a central portion of the substrate W and a plurality of resonators corresponding to a peripheral portion of the substrate W. As a result, density control (control of processing rate) of plasma density at the central portion and the peripheral portion of the substrate W may be performed.

Each embodiment according to the present disclosure should be considered illustrative in all aspects and not restrictive. Each embodiment may be omitted, substituted, or modified in various forms without departing from the scope and spirit of the appended claims.

Also, in each embodiment, for example, a cell-type resonator array structure has been described with reference to a case in which in a lattice pattern on a base plate, a plurality of resonators 301 being capable of resonating with a magnetic field component of electromagnetic waves and having a size smaller than a wavelength of the electromagnetic waves are formed in a lattice pattern on a base plate 320. However, the present disclosure is not limited thereto, and the plurality of resonators 301 may be arranged in any manner along a direction following a plane of the base plate 320. For example, the plurality of resonators 301 may be arranged at predetermined intervals along one direction. Further, when disposed to face the substrate W, the plurality of resonators 401 may be arranged radially from a center similarly to a case of the cell-type resonator array structure 400.

Also, in each embodiment described above, an inductively coupled coil is used as an antenna for introducing electromagnetic waves; however, the present disclosure is not limited thereto, as long as a magnetic field may be generated in a direction penetrating ring members 111 of the plurality of resonators of the resonator array structure 100. Such an antenna for introducing electromagnetic waves is not limited to an inductively coupled coil and may be any type of antenna or mechanism for introducing electromagnetic waves, including a slot antenna, a monopole antenna, a capacitively coupled electrode, or a magnetron.

Also, the embodiments and modifications may be appropriately combined with each other as long as no contradiction arises. For example, a plasma processing apparatus 1 using so-called remote plasma according to the first embodiment may be combined with a plasma processing apparatus 1b using so-called direct plasma according to the third embodiment. In this case, by using resonators having different resonance frequencies in the resonator array structure 100 and the resonator array structure 400, plasma generation may be independently controlled in the respective resonator array structures.

The present disclosure may also adopt configurations as described below.

(1)

A plasma processing apparatus comprising:
a processing container, at least a portion of which is composed of a first dielectric;
a substrate holding part configured to hold a plurality of substrates in the processing container;
an electromagnetic wave generator configured to generate electromagnetic waves for plasma excitation that are supplied into the processing container;
an electromagnetic wave supply part configured to supply the electromagnetic waves into the processing container through the first dielectric; and
a resonator array structure disposed in a region of the processing container, into which the electromagnetic waves are supplied through the first dielectric,
wherein the resonator array structure is configured to include a plurality of resonators that are capable of resonating with a magnetic field component of the electromagnetic waves, that have sizes smaller than a wavelength of the electromagnetic waves, and that are disposed on the same plane, and
the electromagnetic wave supply part is configured to supply a magnetic field component perpendicular to the plane in which the plurality of resonators are arranged.
   (2)

The apparatus of (1), wherein the resonator array structure is disposed in a plasma generation chamber partitioned by a plasma partition wall provided along a longitudinal direction of the processing container.

(3)

The apparatus of (1), wherein the processing container includes a side wall composed of the first dielectric, and
the resonator array structure is disposed between the side wall of the processing container and the substrate holding part.
   (4)

The apparatus of any one of (1) to (3), wherein the plurality of resonators are arranged on the plane parallel to a longitudinal surface of the resonator array structure.

(5)

The apparatus of (4), wherein the plurality of resonators have a structure in which C-shaped ring members made of a conductor are stacked on both surfaces of a dielectric plate,
the C-shaped ring members are covered with a second dielectric, and
the second dielectric has a thickness on a substrate holding part side that is smaller than a thickness on an electromagnetic wave supply side.
   (6)

The apparatus of any one of (1) to (3), wherein the plurality of resonators are arranged on the plane perpendicular to a longitudinal surface of the resonator array structure.

(7)

The apparatus of (6), wherein, in the resonator array structure, a plurality of cells surrounded by the plurality of resonators are formed, and
the cells are arranged in a lattice pattern.
   (8)

The apparatus of any one of (1) to (7), wherein the electromagnetic wave supply part is a coil provided outside the processing container.

(9)

The apparatus of (8), wherein the coil is disposed such that an opening of the coil is parallel to the plurality of resonators.

(10)

The apparatus of (9), wherein the plurality of resonators are arranged in a lattice pattern on the plane parallel to a longitudinal surface of the resonator array structure, and
a plurality of coils are provided at positions corresponding to the plurality of resonators arranged in regions of the resonator array structure corresponding to the respective substrates of the substrate holding part.
   (11)

The apparatus of (9), wherein the plurality of resonators are disposed on the plane perpendicular to a longitudinal surface of the resonator array structure,
a plurality of cells surrounded by the plurality of resonators are formed,
wherein the cells are arranged in a lattice pattern, and
a plurality of coils are provided at positions corresponding to the cells arranged in regions of the resonator array structure corresponding to the respective substrates of the substrate holding part.
   (12)

The apparatus of (11), wherein the coils are arranged in a staggered manner for each of the regions of the resonator array structure.

(13)

The apparatus of any one of (10) to (12), wherein the plurality of resonators have different resonance frequencies for each of the regions.

(14)

The apparatus of (1), wherein the resonator array structure is provided on a plane parallel to the substrate.

(15)

The apparatus of (14), wherein the resonator array structure is provided for each of the plurality of substrates.

(16)

The apparatus of (15), wherein the plurality of resonators are disposed on the plane perpendicular to a longitudinal surface of the resonator array structure.

(17)

The apparatus of (16), wherein, in the resonator array structure, a plurality of cells surrounded by the plurality of resonators are formed, and the cells are arranged in a lattice pattern.

(18)

The apparatus of (15), wherein the plurality of resonators are arranged in a lattice pattern on the plane parallel to a longitudinal surface of the resonator array structure.

(19)

The apparatus of (18), wherein the plurality of resonators have a structure in which C-shaped ring members made of a conductor are stacked on both surfaces of a dielectric plate,
the C-shaped ring members are covered with a second dielectric, and
the second dielectric has a thickness on a processing target surface side of the substrate that is smaller than a thickness on an opposite surface side.
   (20)

The apparatus of (16) or (17), wherein the electromagnetic wave supply part is a coil provided outside the processing container, and
the coil is provided for each resonator array structure corresponding to each substrate of the substrate holding part.
   (21)

The apparatus of (18) or (19), wherein the electromagnetic wave supply part is a coil provided outside the processing container, and
the coil is disposed such that an opening of the coil is parallel to the plurality of resonators and supplies a magnetic field component in a direction in which the magnetic field penetrates a plurality of the resonator array structures.
   (22)

The apparatus of any one of (16) to (21), wherein the plurality of resonators have different resonance frequencies for each resonator array structure.

(23)

The apparatus of any one of (16) to (21), wherein, in the resonator array structure, resonance frequencies of the plurality of resonators corresponding to a central portion of the substrate are different from resonance frequencies of the plurality of resonators corresponding to a peripheral portion of the substrate.

1. A plasma processing apparatus comprising:
a processing container, at least a portion of which is composed of a first dielectric;
a substrate holding part configured to hold a plurality of substrates in the processing container;
an electromagnetic wave generator configured to generate electromagnetic waves for plasma excitation that are supplied into the processing container;
an electromagnetic wave supply part configured to supply the electromagnetic waves into the processing container through the first dielectric; and
a resonator array structure disposed in a region of the processing container, into which the electromagnetic waves are supplied through the first dielectric,
wherein the resonator array structure is configured to include a plurality of resonators that are capable of resonating with a magnetic field component of the electromagnetic waves, that have sizes smaller than a wavelength of the electromagnetic waves, and that are disposed on the same plane, and
the electromagnetic wave supply part is configured to supply a magnetic field component perpendicular to the plane in which the plurality of resonators are arranged.

2. The apparatus of claim 1, wherein the resonator array structure is disposed in a plasma generation chamber partitioned by a plasma partition wall provided along a longitudinal direction of the processing container.

3. The apparatus of claim 1, wherein the processing container includes a side wall composed of the first dielectric, and
the resonator array structure is disposed between the side wall of the processing container and the substrate holding part.

4. The apparatus of claim 1, wherein the plurality of resonators are arranged on the plane parallel to a longitudinal surface of the resonator array structure.

5. The apparatus of claim 4, wherein the plurality of resonators have a structure in which C-shaped ring members made of a conductor are stacked on both surfaces of a dielectric plate,
the C-shaped ring members are covered with a second dielectric, and
the second dielectric has a thickness on a substrate holding part side that is smaller than a thickness on an electromagnetic wave supply side.

6. The apparatus of claim 1, wherein the plurality of resonators are arranged on the plane perpendicular to a longitudinal surface of the resonator array structure.

7. The apparatus of claim 6, wherein, in the resonator array structure, a plurality of cells surrounded by the plurality of resonators are formed, and
the cells are arranged in a lattice pattern.

8. The apparatus of claim 1, wherein the electromagnetic wave supply part is a coil provided outside the processing container.

9. The apparatus of claim 8, wherein the coil is disposed such that an opening of the coil is parallel to the plurality of resonators.

10. The apparatus of claim 9, wherein the plurality of resonators are arranged in a lattice pattern on the plane parallel to a longitudinal surface of the resonator array structure, and
a plurality of coils are provided at positions corresponding to the plurality of resonators arranged in regions of the resonator array structure corresponding to the respective substrates of the substrate holding part.

11. The apparatus of claim 9, wherein the plurality of resonators are disposed on the plane perpendicular to a longitudinal surface of the resonator array structure,
a plurality of cells surrounded by the plurality of resonators are formed,
wherein the cells are arranged in a lattice pattern, and
a plurality of coils are provided at positions corresponding to the cells arranged in regions of the resonator array structure corresponding to the respective substrates of the substrate holding part.

12. The apparatus of claim 11, wherein the coils are arranged in a staggered manner for each of the regions of the resonator array structure.

13. The apparatus of claim 10, wherein the plurality of resonators have different resonance frequencies for each of the regions.

14. The apparatus of claim 1, wherein the resonator array structure is provided on a plane parallel to the substrate.

15. The apparatus of claim 14, wherein the resonator array structure is provided for each of the plurality of substrates.

16. The apparatus of claim 15, wherein the plurality of resonators are disposed on the plane perpendicular to a longitudinal surface of the resonator array structure.

17. The apparatus of claim 16, wherein, in the resonator array structure, a plurality of cells surrounded by the plurality of resonators are formed, and
the cells are arranged in a lattice pattern.

18. The apparatus of claim 15, wherein the plurality of resonators are arranged in a lattice pattern on the plane parallel to a longitudinal surface of the resonator array structure.

19. The apparatus of claim 18, wherein the plurality of resonators have a structure in which C-shaped ring members made of a conductor are stacked on both surfaces of a dielectric plate,
the C-shaped ring members are covered with a second dielectric, and
the second dielectric has a thickness on a processing target surface side of the substrate that is smaller than a thickness on an opposite surface side.

20. The apparatus of claim 16, wherein the electromagnetic wave supply part is a coil provided outside the processing container, and
the coil is provided for each resonator array structure corresponding to each substrate of the substrate holding part.

21. The apparatus of claim 18, wherein the electromagnetic wave supply part is a coil provided outside the processing container, and
the coil is disposed such that an opening of the coil is parallel to the plurality of resonators and supplies a magnetic field component in a direction in which the magnetic field penetrates a plurality of the resonator array structures.

22. The apparatus of claim 16, wherein the plurality of resonators have different resonance frequencies for each resonator array structure.

23. The apparatus of claim 16, wherein, in the resonator array structure, resonance frequencies of the plurality of resonators corresponding to a central portion of the substrate are different from resonance frequencies of the plurality of resonators corresponding to a peripheral portion of the substrate.
